(19) United States
(12) Patent Application Publication
(10) Pub. No.: US 2025/0393329 A1
(43) Pub. Date: Dec. 25, 2025

(54) IMAGE SENSOR AND METHOD FOR FABRICATING THE SAME

(71) Applicant: SAMSUNG ELECTRONICS CO., LTD., Suwon-si (KR)

(72) Inventor: Kwang-Min LEE, Suwon-si (KR)

(73) Assignee: SAMSUNG ELECTRONICS CO., LTD., Suwon-si (KR)

(21) Appl. No.: 18/987,960

(22) Filed: Dec. 19, 2024

(30) Foreign Application Priority Data
Jun. 21, 2024 (KR) 10-2024-0081205

(51) Int. Cl. H10F 39/00; H10F 39/18

(52) U.S. Cl. CPC H10F 39/811; H10F 39/014; H10F 39/182; H10F 39/809

(57) ABSTRACT

An image sensor includes a first substrate region including a first surface and a second surface, a pad groove adjacent to the second surface, a first conductive pad in the pad groove, a second conductive pad on the first conductive pad and within the pad groove, and a plurality of vias electrically coupled with the first conductive pad and at least partially penetrating the first substrate region.

### CROSS-REFERENCE TO RELATED APPLICATIONS

The application claims benefit of priority under 35 U.S.C. § 119 to Korean Patent Application No. 10-2024-0081205, filed on Jun. 21, 2024, in the Korean Intellectual Property Office, the disclosure of which is incorporated by reference herein in its entirety.

### BACKGROUND

### 1. Field

The present disclosure relates generally to image sensors, and more particularly, to an image sensor and a method of manufacturing the image sensor.

### 2. Description of Related Art

Image sensors may refer to devices that may convert optical image signals into electrical signals, and may include, for example, but not be limited to, charge coupled device (CCD) image sensors, complementary metal oxide semiconductor (CMOS) image sensors or the like. The image sensors may include a plurality of pixels. Each pixel in the image sensor may include a light-receiving region that may receive incident light and may convert the received incident light into an electrical signal. Each pixel may also include a pixel circuit that may output a pixel signal using charges generated in the light-receiving region.

An aluminum pad that constitutes an input/output (I/O) pad arranged on upper portions of the image sensors and a backside via silicon (BVS) may be spaced apart from each other, and a metal wire for electrically connecting the aluminum pad and the BVS may be protruded on a backside of a substrate region.

However, the metal wire protruding on the backside of the substrate region may prevent a color filter from being uniformly formed. Therefore, to reduce manufacturing defects of the color filter, it may be necessary to develop the image sensors in which the metal wire does not protrude on the backside of the substrate region.

### SUMMARY

One or more example embodiments of the present disclosure provide image sensors with improved photoelectric conversion efficiency, when compared to related image sensors.

According to an aspect of the present disclosure, an image sensor includes a first substrate region including a first surface and a second surface, a pad groove adjacent to the second surface, a first conductive pad in the pad groove, a second conductive pad on the first conductive pad and within the pad groove, and a plurality of vias electrically coupled with the first conductive pad and at least partially penetrating the first substrate region.

According to an aspect of the present disclosure, a method of manufacturing an image sensor includes forming a second substrate region on a first surface of a first substrate region including the first surface and a second surface, forming a pad groove by etching the first substrate region adjacent to the second surface, forming a first conductive pad in the pad groove, forming a second conductive pad at least partially covering the first conductive pad in the pad groove, exposing the first conductive pad and forming holes at least partially penetrating the first substrate region, and forming a plurality of vias electrically coupled with the first conductive pad in the holes. The second conductive pad is within the pad groove.

According to an aspect of the present disclosure, an image sensor includes a first stacked structure, a second stacked structure electrically coupled with the first stacked structure, a pad groove on an opposite side of the second stacked structure with respect to the first stacked structure, a first conductive pad in the pad groove, a second conductive pad on the first conductive pad and positioned in the pad groove, and a plurality of vias extending from the first conductive pad toward the second stacked structure. A top surface of the second conductive pad is positioned at a first level lower than or equal to a second level of a second surface of the first conductive pad.

Additional aspects will be set forth in part in the description which follows and, in part, will be apparent from the description, and/or may be learned by practice of some example embodiments of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a block diagram of an image sensor, according to some example embodiments;

FIG. 2 is a plan view of a pixel array of FIG. 1, according to some example embodiments;

FIG. 3 is an equivalent circuit diagram of the pixel group of FIG. 1, according to some example embodiments;

FIG. 4A is a plan view of the pixel array and the peripheral circuitry of FIG. 1, according to some example embodiments;

FIG. 4B is a cross-sectional view corresponding to line A-A′ in FIG. 4A, according to some example embodiments;

FIG. 4C is a top view of region P1 of FIG. 4B, according to some example embodiments;

FIGS. 5 to 11 are cross-sectional views corresponding to line A-A′in FIG. 4B of a method of manufacturing an image sensor, according to some example embodiments;

FIG. 12A is a cross-sectional view illustrating an image sensor, according to some example embodiments;

FIG. 12B is a plan view of the image sensor of FIG. 12A, according to some example embodiments;

FIG. 13A is a cross-sectional view illustrating an image sensor, according to some example embodiments;

FIG. 13B is a plan view of the image sensor of FIG. 13A, according to some example embodiments;

FIG. 14 is a cross-sectional view illustrating an image sensor, according to some example embodiments;

FIG. 15 is a cross-sectional view illustrating an image sensor, according to some example embodiments;

FIG. 16 is a cross-sectional view illustrating an image sensor, according to some example embodiments;

FIG. 17 is a cross-sectional view illustrating an image sensor, according to some example embodiments;

FIG. 18 is a cross-sectional view illustrating an image sensor, according to some example embodiments;

FIG. 19 is a cross-sectional view illustrating an image sensor, according to some example embodiments;

FIG. 20 is a cross-sectional view illustrating an image sensor, according to some example embodiments;

FIG. 21 is a cross-sectional view illustrating an image sensor, according to some example embodiments;

FIG. 22 is a cross-sectional view illustrating an image sensor, according to some example embodiments;

FIG. 23 is a cross-sectional view illustrating an image sensor, according to some example embodiments;

FIG. 24 is a cross-sectional view illustrating an image sensor, according to some example embodiments; and

FIG. 25 is a cross-sectional view illustrating an image sensor, according to some example embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

As used herein, each of the terms “CaF₂”, “GeNₓ”, “GeOₓ”, “GeOₓN_{y}”, “NbN”, “SiCₓN_{y}”, “Si—Ge”, “SiNₓ”, “SiOₓ”, “SiOₓN_{y}”, “TiN”, “WN”, and the like may refer to a material made of elements included in each of the terms and is not a chemical formula representing a stoichiometric relationship.

Hereinafter, various embodiments of the present disclosure are described with reference to the accompanying drawings.

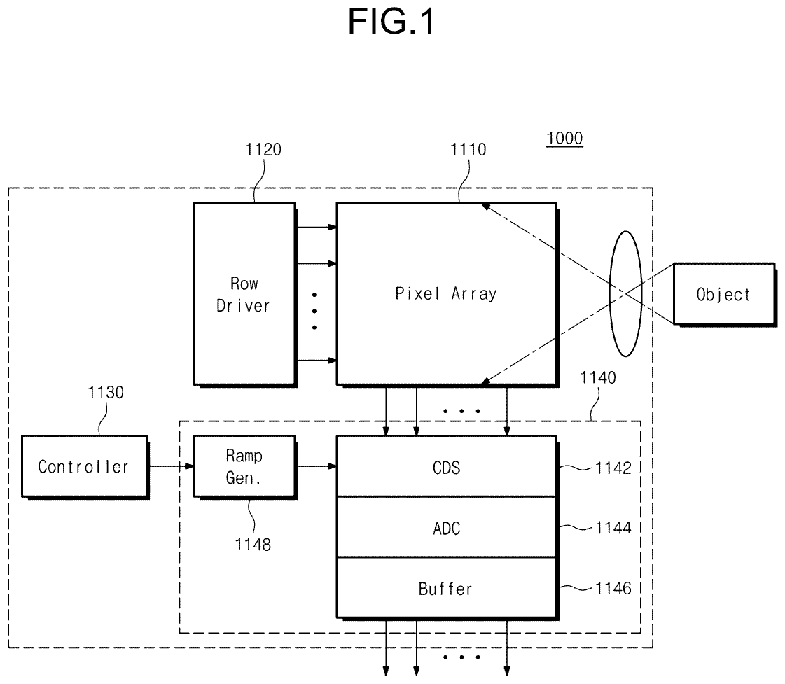

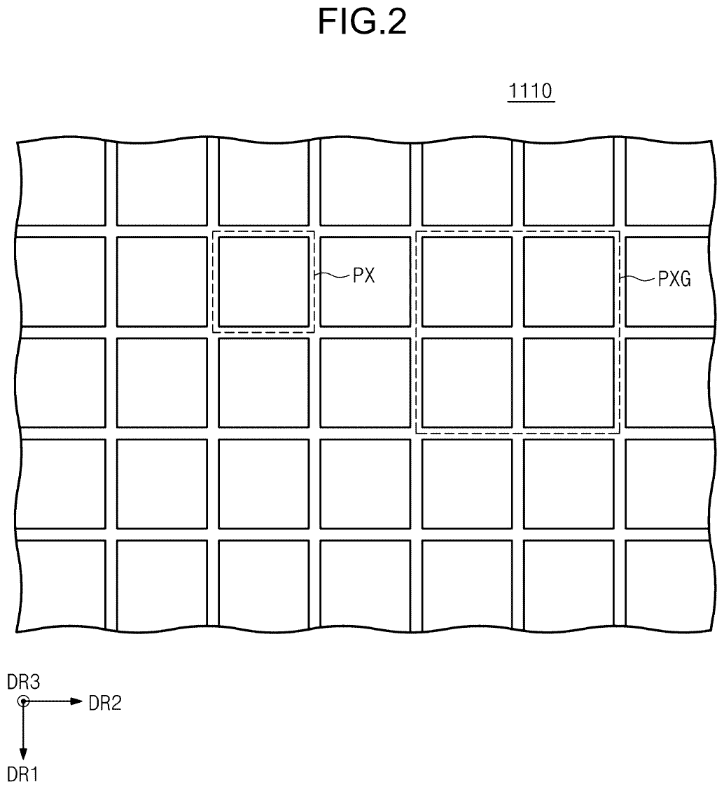

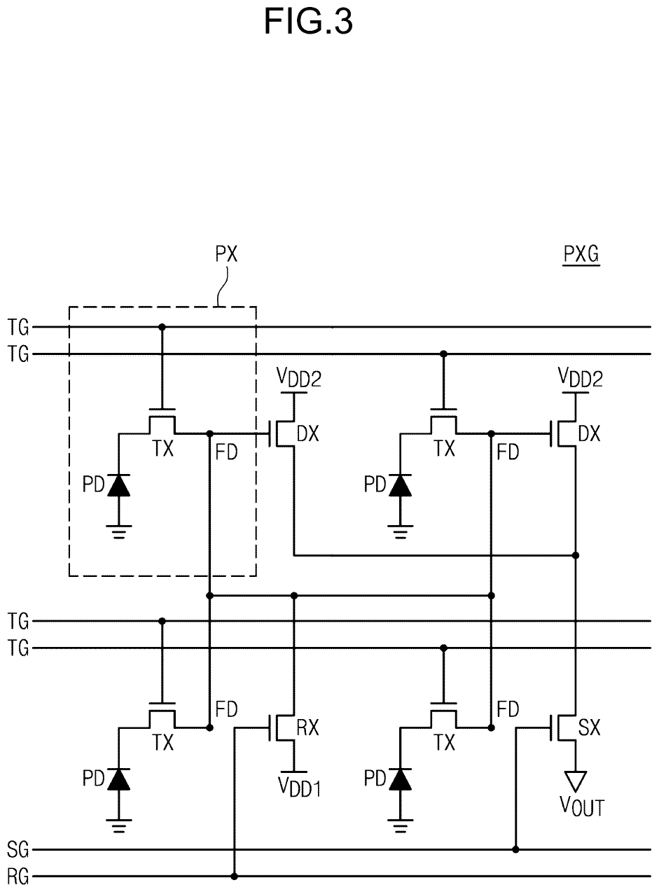

FIG. 1 is a block diagram of an image sensor, according to some example embodiments. FIG. 2 is a plan view of a pixel array of FIG. 1, according to some example embodiments. FIG. 3 is an equivalent circuit diagram of the pixel group of FIG. 1, according to some example embodiments.

Referring to FIG. 1, an image sensor 1000 may be provided. The image sensor 1000 may be mounted in an electronic device having an image or light sensing function. For example, the electronic device may be and/or may include, but not be limited to, a camera, a smartphone, a wearable device, an Internet of Things (IoT) device, a tablet computer, a personal computer (PC), a personal digital assistant (PDA), a portable multimedia player (PMP), a navigation device, or the like. The image sensor 1000 may be mounted in electronic devices provided as components in various devices (e.g., vehicles, furniture, manufacturing facilities, doors, various measuring devices, or the like).

The image sensor 1000 may include a control unit including a pixel array 1110, a controller 1130, a row driver 1120, and a pixel signal processor 1140.

As illustrated in FIG. 2, the pixel array 1110 may include a plurality of pixels PX two-dimensionally (2D) arranged along a first direction DR1 and a second direction DR2. The second direction DR2 may be different from the first direction DR1. The second direction DR2 may be perpendicular to the first direction DR1. The plurality of pixels PX may be arranged in a regular pattern to generate a relatively high-quality image. For example, the plurality of pixels PX may be arranged in a Bayer pattern and/or a chess mosaic pattern. When the plurality of pixels PX are arranged in the Bayer pattern, the pixels in the pixel array 1110 may receive red light, green light, and blue light, respectively. However, the present disclosure is not limited in this regard. For example, in some example embodiments, the plurality of pixels PX may receive cyan light, magenta light, and/or yellow light. Each of the pixels may include a photoelectric conversion device. The photoelectric conversion device may absorb light to generate charge carriers (e.g., electrons or holes). For example, the photoelectric conversion device may include photodiodes, phototransistors, photogates, pinned photodiodes, or a combination thereof. Output voltages of the plurality of pixels PX may be determined based on the generated charge carriers.

The pixel array 1110 may include a pixel group PXG. The pixel group PXG may be and/or may include a set of pixels PX sharing a reset transistor RX, a selection transistor SX, and a source follower transistor DX. Although the pixel group PXG is illustrated as being composed of four (4) pixels PX, the present disclosure is not limited in this regard. For example, in some example embodiments, the pixel group PXG may include less than (e.g., three (3) or less) or more than four (e.g., five (5) or more) pixels PX.

The pixel array 1110 may be driven by receiving, from the row driver 1120, a plurality of driving signals, such as, but not limited to, a row selection signal, a reset signal, a charge transfer signal, or the like. The row driver 1120 may provide the plurality of driving signals to the pixel array 1110 for driving the plurality of pixels PX. In some example embodiments, the driving signals may be provided for each row of the pixel array 1110. Pixels belonging to one row of the pixel array 1110 selected by the driving signals of the row driver 1120 may be simultaneously (e.g., at a substantially similar time period) activated by a signal output from the row driver 1120. The pixels belonging to the selected row may provide output voltages according to absorbed light to output lines of corresponding columns. In some example embodiments, the pixels belonging to the selected one row may provide the output voltages together. The output voltages may be provided to a correlated double sampler (CDS) 1142.

The pixel signal processor 1140 may include the CDS 1142, an analog-to-digital converter (ADC) 1144, and a buffer 1146. The CDS 1142 may sample and hold the output voltages provided by the pixel array 1110. The CDS 1142 may reduce noise and may improve a signal noise ratio (SNR). That is, the CDS 1142 may be configured to remove noise voltages from the output voltages of the pixel. For example, the CDS 1142 may double sample a specific noise level and a signal level by an output signal, and output a difference level corresponding to a difference between the noise level and the signal level. The CDS 1142 may output a result based on ramp signals generated by a ramp signal generator 1148.

The analog-to-digital converter 1144 may convert an analog signal corresponding to the difference level received from the CDS 1142 into a digital signal. The buffer 1146 may latch digital signals, and the latched signals may be sequentially output to the outside of the image sensor 1000 and transferred to an image processor.

The controller 1130 may control the row driver 1120 so that the pixel array 1110 may absorb light to accumulate charge carriers, temporarily store the accumulated charge, and output an electrical signal according to the accumulated charge to the outside of the pixel array 1110. In addition, the controller 1130 may control the pixel signal processor 1140 to measure an output voltage provided by the pixel array 1110.

As described herein, any devices, systems, modules, portions, units, controllers, circuits, and/or portions thereof according to any of the example embodiments, and/or any portions thereof (including, without limitation, the image sensor 1000, the pixel array 1110, the row driver 1120, the controller 1130, the pixel signal processor 1140, the CDS 1142, the ADC 1144, the buffer 1146, the ramp signal generator 1148, any portion thereof, or the like) may include, may be included in, and/or may be implemented by one or more instances of processing circuitry such as hardware including logic circuits; a hardware/software combination such as a processor executing software, or a combination thereof. For example, the processing circuitry may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), a programmable logic unit (PLU), a microprocessor, an application-specific integrated circuit (ASIC), a neural network processing unit (NPU), an electronic control unit (ECU), an image signal processor (ISP), or the like. In some example embodiments, the processing circuitry may include a non-transitory computer readable storage device (e.g., a memory), for example, a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Referring to FIG. 3, each pixel of the plurality of pixels PX may include a photoelectric conversion device PD, a transfer transistor TX, and a floating diffusion region FD. The photoelectric conversion device PD may generate and accumulate photo charges in proportion to the amount of light incident from the outside, and may include a photodiode, a phototransistor, a photogate, a pinned photodiode, or a combination thereof.

The transfer transistor TX may include a transfer gate TG. The transfer gate TG may transfer charge carriers generated by the photoelectric conversion device PD to the floating diffusion region FD. A transfer control voltage provided from the row driver 1120 may be applied to the transfer gate TG. For example, a channel may be formed between the photoelectric conversion device PD and the floating diffusion region FD by the transfer control voltage applied to the transfer gate TG. Charge carriers generated by the photoelectric conversion device PD may move to the floating diffusion region FD along the channel between the photoelectric conversion device PD and the floating diffusion region FD. A drain terminal of the transfer transistor TX may be electrically connected to the floating diffusion region FD, and a source terminal of the transfer transistor TX may be electrically connected to the photoelectric conversion device PD.

The floating diffusion region FD may receive, accumulate, and store charges generated by the photoelectric conversion device PD. The source follower transistor DX may be controlled according to the amount of charge accumulated in the floating diffusion region FD. A gate terminal of the source follower transistor DX may be electrically connected to the floating diffusion region FD. A second power voltage V_{DD2} may be applied to a drain terminal of the source follower transistor DX. A source terminal of the source follower transistor DX may be electrically connected to a drain terminal of the selection transistor SX. The source follower transistor DX may be a source follower buffer amplifier that outputs a current proportional to the amount of charge accumulated in the floating diffusion region FD.

The reset transistor RX may periodically reset charges accumulated in the floating diffusion region FD. A gate terminal of the reset transistor RX may be electrically connected to a reset signal line RG. A drain terminal of the reset transistor RX may be connected to the floating diffusion region FD. A first power voltage V_{DD1} may be applied to a source terminal of the reset transistor RX. In some example embodiments, the first power voltage V_{DD1} may be equal or substantially equal to the second power voltage V_{DD2}. When the reset transistor RX is turned on, the first power voltage V_{DD1} applied to the source terminal of the reset transistor RX may be transferred to the floating diffusion region FD. When the reset transistor RX is turned on, charges accumulated in the floating diffusion region FD may be discharged to reset the floating diffusion region FD. When electrons are charge carriers, the voltage of the floating diffusion region FD may decrease as electrons are accumulated in the floating diffusion region FD. When the reset transistor RX is turned on, electrons of the floating diffusion region FD are discharged to the outside, and the voltage of the floating diffusion region FD may increase to the first power voltage V_{DD1}. As the first power voltage V_{DD1} is applied to the floating diffusion region FD, the first power voltage V_{DD1} may be applied to the gate terminal of the source follower transistor DX to reset the output of the source follower transistor DX.

The selection transistor SX may select a plurality of pixels PX in each row. The selection transistor SX may transfer current generated by the source follower transistor DX included in each of the selected pixels to an output line (not illustrated). A drain terminal, a source terminal, and a gate terminal of the selection transistor SX may be electrically connected to the source terminal, the output line, and the row selection line SG of the source follower transistor DX, respectively. A selection control signal applied from the row selection line SG may be applied to the gate terminal of the selection transistor SX to output a signal generated by the source follower transistor DX to the output line.

As illustrated in FIG. 3, in some example embodiments a pixel group PXG may include multiple pixels PX sharing a floating diffusion node FD and further sharing a reset transistor RX, a selection transistor SX, and at least one of a set of source follower transistor DX.

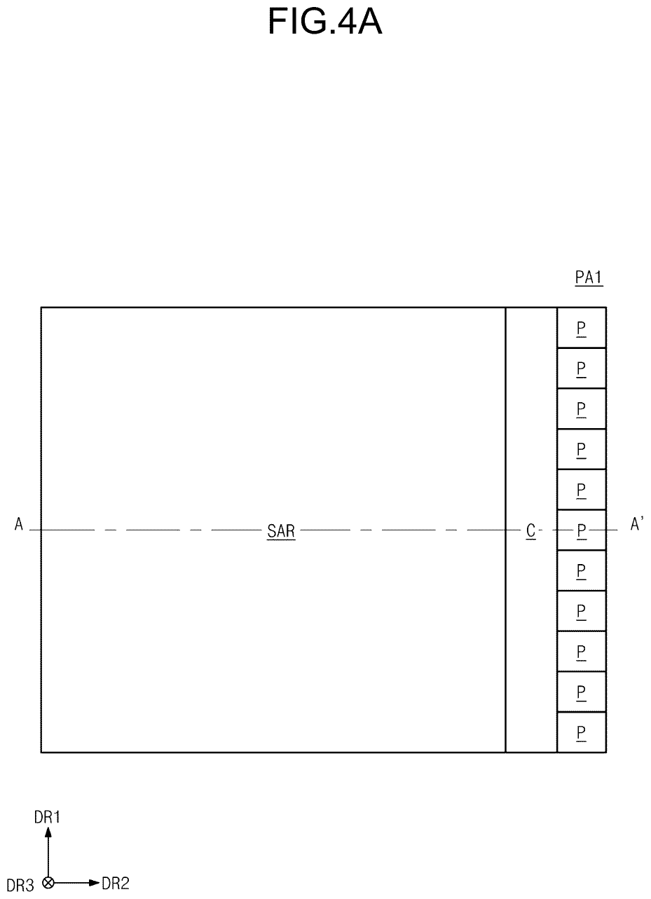

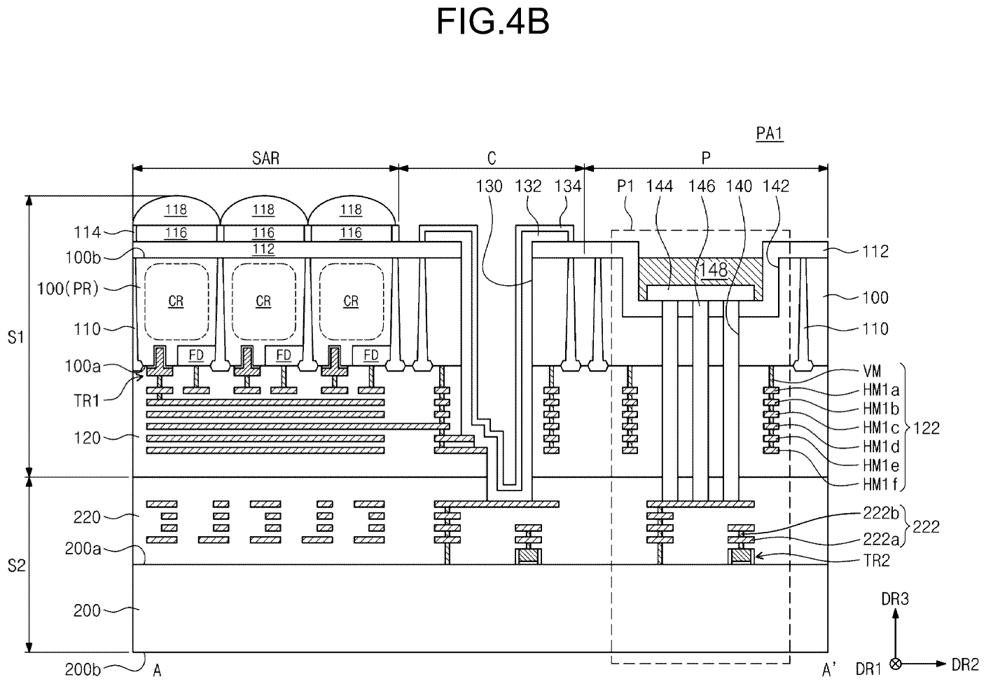

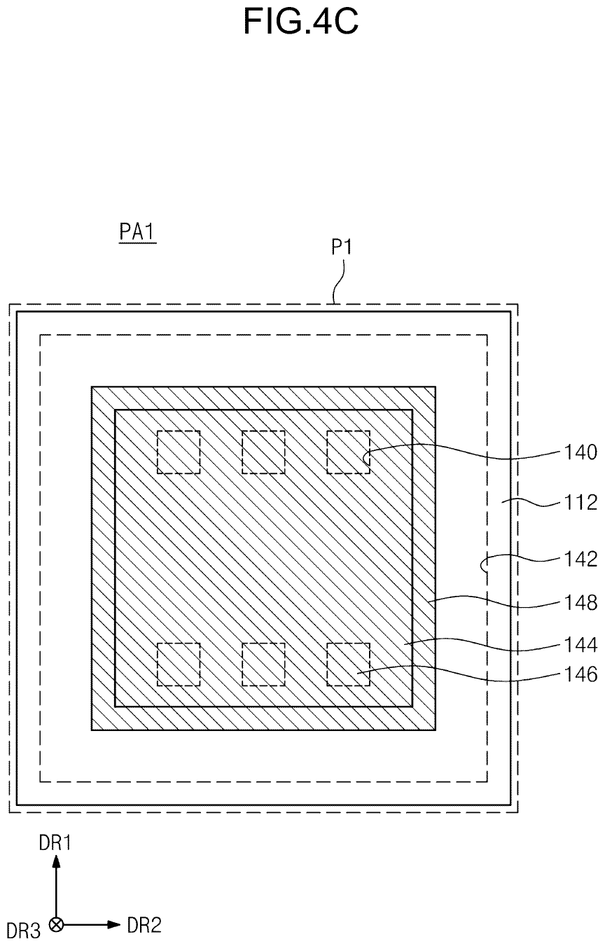

FIG. 4A is a plan view of the pixel array and the peripheral circuitry of FIG. 1, according to some example embodiments. FIG. 4B is a cross-sectional view corresponding to line A-A′ of FIG. 4A, according to some example embodiments. FIG. 4C is a top view of region P1 in FIG. 4B, according to some example embodiments.

Referring to FIGS. 4A to 4C, from a plan view, an image sensor PA1 including a sensor array region SAR, a connection region C, and a pad region P may be provided. The image sensor PA1 including a first stacked structure S1 and a second stacked structure S2 may be provided. The first stacked structure S1 may be provided on the second stacked structure S2.

The first stacked structure S1 may include a first substrate region 100. The first substrate region 100 may be provided within the sensor array region SAR, the connection region C, and the pad region P. The first substrate region 100 may include a semiconductor material. For example, the first substrate region 100 may include silicon (Si), germanium (Ge), or silicon-germanium (Si—Ge). The first substrate region 100 may have a first conductivity type. For example, the first conductivity type may be p-type and/or n-type. When the conductivity type of the first substrate region 100 is p-type, the first substrate region 100 may be and/or may include a silicon (Si) region containing a group III element or a group II element as an impurity. For example, the group III element may be and/or may include, but not be limited to, boron (B), aluminum (Al), gallium (Ga), indium (In) or the like. When the conductivity type of the first substrate region 100 is n-type, the first substrate region 100 may be and/or may include a silicon (Si) region containing a group V element, a group VI element, or a group VII element as an impurity. For example, the group V elements may include, but not be limited to, phosphorus (P), arsenic (As), antimony (Sb), or the like. The first substrate region 100 may be and/or may include an epitaxial layer formed by an epitaxial growth process. The crystal structure of the first substrate region 100 may include at least one of a single-crystalline structure, a polycrystalline structure, or an amorphous structure. The first substrate region 100 may include a first surface 100a and a second surface 100b facing opposite directions. The first surface 100a and the second surface 100b may extend along the first direction DR1 and the second direction DR2. The first surface 100a may be spaced apart from the second surface 100b along the third direction DR3.

The first substrate region 100 may include pixel regions PR. The pixel regions PR may be provided within the sensor array region SAR. The pixel regions PR may refer to the first substrate region 100 included in the pixel PX. Each of the pixel regions PR may include photoelectric conversion regions CR. In some example embodiments, the photoelectric conversion regions CR may include a photodiode including a first conductivity type region and a second conductivity type region. For example, the photoelectric conversion regions CR may include a pn photodiode. When the conductivity type of the first substrate region 100 is p-type, the p-type region of the photoelectric conversion regions CR may be the first substrate region 100, or the group III element or the group II element may be formed by implanting an element as impurity to the first substrate region 100. The n-type region of the photoelectric conversion regions CR may be formed by implanting a group V, VI, or VII elements as an impurity into the first substrate region 100. The p-type and n-type regions may have a potential gradient due to the p-n junction structure. In some example embodiments, the photoelectric conversion regions CR may include photodiodes. In some other example embodiments, the photoelectric conversion regions CR may include phototransistors, photogates, or pinned photodiodes.

When light is incident on the photoelectric conversion regions CR, electron-hole pairs may be generated in the photoelectric conversion regions CR. For example, the electron-hole pairs may be generated in a depletion region formed in a region adjacent to a p-n junction. The stronger the intensity of light incident on the photoelectric conversion regions CR, the more electron-hole pairs may be generated. When a reverse bias is applied to the photoelectric conversion regions CR, the charge carriers (e.g., electrons or holes) may be accumulated in the photoelectric conversion regions CR. The charge carriers accumulated in the photoelectric conversion regions CR may be transferred to floating diffusion regions FD along a channel formed by a voltage applied to gate electrodes. The photoelectric conversion regions CR may be spaced apart from the floating diffusion regions FD.

The first stacked structure S1 may include separators 110. The separators 110 may be provided within the sensor array region SAR, the connection region C, and the pad region P. The separators 110 may be provided in the first substrate region 100. The separators 110 may define the pixel regions PR. For example, the separators 110 may surround the pixel regions PR. The separators 110 may extend along the third direction DR3. Widths of the separators 110 may become smaller and closer to the second surface 100b of the first substrate region 100. However, the present disclosure is not limited in this regard. The widths of the separators 110 may be determined according to a manufacturing process and required characteristics of the image sensor PA1. The widths of the separators 110 may be the size of the separators 110 along the second direction DR2. In some example embodiments, the separators 110 may include a device isolation layer and a pixel isolation layer. The device isolation layer and the pixel isolation layer may be arranged along the third direction DR3. The device isolation layer may be disposed adjacent to the first surface 100a of the first substrate region 100. The pixel isolation layer may be disposed adjacent to the second surface 100b of the first substrate region 100.

The device isolation layer may define active regions. For example, the device isolation layer may be a shallow trench isolation (STI) layer. From a plan view, the device isolation layer may surround the active regions. The active regions may be regions where the gate electrodes and the floating diffusion regions FD are provided. The device isolation layer may include a silicon-based insulating material (e.g., at least one of silicon oxide (SiOₓ), silicon nitride (SiNₓ), silicon oxynitride (SiOₓN_{y}), or a combination thereof).

The pixel isolation layer may be configured to optically and/or electrically separate adjacent pixels from each other. For example, the pixel isolation layer may be and/or may include a deep trench isolation (DTI) layer. In some example embodiments, the pixel isolation layer may prevent or reduce electrical crosstalk, which reduces the signal-to-noise ratio (SNR), by exchanging the charge carriers between adjacent pixel regions PR. For example, the pixel isolation layer may include, but not be limited to, electrically conductive materials (e.g., at least one of doped polysilicon, metal, metal silicide, metal nitride, or a metal-containing material), electrically insulating materials (e.g., a silicon-based insulating material (e.g. at least one of silicon oxide (SiOₓ), silicon nitride (SiNₓ), and silicon oxynitride (SiOₓN_{y})), or high-k dielectric materials (e.g., metal oxides containing at least one of hafnium (Hf), zirconium (Zr), aluminum (Al), tantalum (Ta), titanium (Ti), yttrium (Y), lanthanum (La), or the like).

In some example embodiments, a sidewall of the pixel isolation layer may be doped with a highly reflective material. For example, the highly reflective material may be and/or may include, but not be limited to, boron (B). In some example embodiments, when the pixel isolation layer includes electrically conductive materials, a negative fixed charge layer may be provided between the pixel isolation layer and the first substrate region 100. For example, the negative fixed charge layer may include metal oxides containing at least one of hafnium (Hf), zirconium (Zr), aluminum (Al), tantalum (Ta), titanium (Ti), yttrium (Y), lanthanum (La), or the like. However, a structure of the pixel isolation layer may be determined as needed, according to design constraints. In some example embodiments, the pixel isolation layer may be an insulating layer having a single-layer structure.

The first layered structure S1 may include the floating diffusion regions FD. The floating diffusion regions FD may be provided within the sensor array region SAR. The floating diffusion regions FD may be provided in the first substrate region 100. The floating diffusion regions FD may be provided in each of the pixel regions PR. The floating diffusion regions FD may be disposed on one side of first transistors TR1. The floating diffusion regions FD may be disposed adjacent to the first surface 100a of the first substrate region 100. The floating diffusion regions FD may have a second conductivity type. In some example embodiments, the floating diffusion regions FD may be formed by implanting second impurities into a region adjacent to the first surface 100a of the first substrate region 100. The floating diffusion regions FD may receive and accumulate the charge carriers provided from the pixel regions PR. The floating diffusion regions FD may be included in a drain of the transfer transistor (e.g., transfer transistor TX). The floating diffusion region FD may be electrically connected to the source of the reset transistor (e.g., reset transistor RX). The floating diffusion region FD may be electrically connected to the source follower gate of the source follower transistor (e.g., source follower transistor DX).

The first stacked structure S1 may include the first transistors TR1. The first transistors TR1 may be provided within the sensor array region SAR. The first transistors TR1 may be provided in the pixel regions PR. In some example embodiments, the first transistors TR1 may be provided on the first surface 100a of the first substrate region 100. In some example embodiments, the first transistors TR1 may be transfer transistors. In an embodiment, at least one of the reset transistor, the source follower transistor, and the selection transistor may be further included in the pixel region PR.

The first transistors TR1 may include the gate electrodes. For example, the gate electrodes may include, but not be limited to, electrically conductive materials. As another example, the gate electrodes may be polysilicon (e.g., doped polysilicon), metal silicide, or metal (e.g., at least one of titanium (Ti), tantalum (Ta), tungsten (W), molybdenum (Mo), cobalt (Co), copper (Cu), aluminum (Al), silver (Ag), gold (Au), platinum (Pt), ruthenium (Ru), titanium nitride (TiN), tungsten nitride (WN), niobium nitride (NbN), or a combination thereof).

The first transistors TR1 may include gate insulating layers. For example, the gate insulating layers may be provided between the gate electrodes and the first surface 100a of the first substrate region 100. In some example embodiments, the gate insulating layers may extend along surfaces of the gate electrodes facing the first surface 100a to electrically separate the gate electrodes from the first substrate region 100. For example, the gate insulating layers may include silicon-based insulating materials (e.g., at least one of silicon oxide (SiOₓ), silicon nitride (SiNₓ), and silicon oxynitride (SiOₓN_{y})) or high-k dielectric materials (e.g., metal oxides containing at least one of hafnium (Hf), zirconium (Zr), aluminum (Al), tantalum (Ta), titanium (Ti), yttrium (Y), lanthanum (La), or the like).

The first stacked structure S1 may include a lower insulating layer 112. The lower insulating layer 112 may be provided within the sensor array region SAR, the connection region C, and the pad region P. The lower insulating layer 112 may be provided on the second side 100b. In some example embodiments, the lower insulating layer 112 may be provided to protect the pixel regions PR. For example, the lower insulating layer 112 may include, but not be limited to, electrically insulating materials (e.g., at least one of silicon oxide (SiOₓ), aluminum oxide (AlOₓ), hafnium oxide (HfOₓ), titanium oxide (TiOₓ), or a combination thereof). As another example, the lower insulating layer 112 may have a single-layer structure and/or a multi-layer structure of two (2) or more layers.

The first stacked structure S1 may include a grid 114. The grid 114 may be provided within the sensor array region SAR. The grid 114 may be provided on the lower insulating layer 112. The grid 114 may be provided between color filters 116. The grid 114 may be configured to optically separate the color filters 116 that may be immediately adjacent to each other. The grid 114 may correspond to the separator 110. For example, the grid 114 may overlap the separator 110 along the third direction DR3. In some example embodiments, the grid 114 may include, but not be limited to, electrically conductive materials (e.g., at least one of titanium (Ti) or titanium nitride (TiN)). In some example embodiments, the grid 114 may include a low refractive index material with insulating properties. For example, the low refractive index material may include a polymer containing nanoparticles (e.g., silica). In some example embodiments, the grid 114 may have a single-layer structure or a multi-layer structure of two or more layers.

The first layered structure S1 may include the color filters 116. The color filters 116 may be provided within the sensor array region SAR. The color filters 116 may be provided on the lower insulating layer 112. The color filters 116 may be arranged in a direction parallel to the first surface 100a (e.g., in the first direction DR1, the second direction DR2, or a combined direction of the first direction DR1 and the second direction DR2). The color filters 116 may be configured to transmit light of a required wavelength band. In some example embodiments, the color filters 116 may transmit red light, green light, or blue light. However, the present disclosure is not limited in this regard. For example, the color filters 116 may transmit cyan light, magenta light, and yellow light. From a plan view, the color filters 116 may be provided to correspond to the pixel regions PR. For example, incident light that passes through the color filters 116 may be incident on the pixel regions PR corresponding to the color filters 116. As another example, the color filters 116 may be provided by a dyeing method, a pigment dispersion method, an electrodeposition method, and a printing method.

The first layered structure S1 may include a microlens 118. The microlens 118 may be provided within the sensor array region SAR. The microlens 118 may overlap the pixel regions PR along the third direction DR3. The microlens 118 may be configured to focus incident light and provide the focused incident light to the pixel regions PR. The microlens 118 may have a convex shape in the third direction DR3. The microlens 118 may include glasses (e.g., at least one of silicon-based glasses, and chalcogenide-based glasses), thermosetting resins (e.g., at least one of polycarbonate-based resins, and polyester-based resins), photocurable resins (e.g., at least one of acrylic-based resins, epoxy-based resins, and polyurethane-based resins), and fluoride-based materials (e.g., calcium fluoride (CaF₂)).

The first stacked structure S1 may include a first wire insulating layer 120. The first wire insulating layer 120 may be provided within the sensor array region SAR, the connection region C, and the pad region P. The first wire insulating layer 120 may be provided on the first surface 100a. In some example embodiments, the first wire insulating layer 120 may have a single-layer structure. In some other example embodiments, the first wire insulating layer 120 may have a multi-layer structure. For example, the first wire insulating layer 120 may include, but not be limited to, electrical insulating materials. As another example, the first wire insulating layer 120 may include at least one of silicon oxide (SiOₓ), silicon nitride (SiNₓ), silicon oxynitride (SiOₓN_{y}), germanium oxide (GeOₓ), germanium nitride (GeNₓ), and germanium oxynitride (GeOₓN_{y}), or a combination thereof.

The first stacked structure S1 may include first wires 122. The first wires 122 may be provided within the sensor array region SAR, the connection region C, and the pad region P. The first wires 122 may be provided in the first wire insulating layer 120. The first wires 122 may include a first horizontal wire HM1a, a second horizontal wire HM1b, a third horizontal wire HM1c, a fourth horizontal wire HM1d, a fifth horizontal wire HM1e, a sixth horizontal wire HM1f, and first vertical wires VM. The first to sixth horizontal wires HM1a to HM1f may be referred to as first horizontal wires. The first to sixth horizontal wires HM1a to HM1f may be provided along a direction perpendicular to the first surface 100a (e.g., third direction DR3). The first to sixth horizontal wires HM1a to HM1f may be provided to surround second vias 146. The first horizontal wire HM1a may be provided adjacent to a top surface of the first wire insulating layer 120. The sixth horizontal wire HM1f may be provided adjacent to a bottom surface of the first wire insulating layer 120. The first vertical wires VM may extend along a direction perpendicular to the first surface 100a (e.g., third direction DR3). The first wires 122 illustrated in FIG. 4B are exemplary. That is, the shape and number of the first wires 122 may be determined as needed, according to design constraints. The first wires 122 may output electrical signals generated in the pixel regions PR to the outside. For example, the first wires 122 may be provided between the floating diffusion regions FD and other electrical components to provide an electrical connection between the floating diffusion regions FD and other electrical components. In an embodiment, the first wires 122 may include, but not be limited to, electrically conductive materials. For example, the first wires 122 may include at least one of titanium (Ti), tantalum (Ta), tungsten (W), molybdenum (Mo), cobalt (Co), copper (Cu), aluminum (Al), and silver (Ag), gold (Au), platinum (Pt), ruthenium (Ru), titanium nitride (TiN), tungsten nitride (WN), and niobium nitride (NbN). The first wires 122 may be electrically connected to at least one of a transmission gate, a source follower gate, a reset gate, and a selection gate. For example, the first wires 122 may be configured to apply the power supply voltage VDD to a drain of the reset transistor RX or a drain of the source follower transistor DX.

The first stacked structure S1 may include a first hole 130. The first hole 130 may be provided within the connection region C. In some example embodiments, the first hole 130 may extend from the second surface 100b to an upper portion of the second stacked structure S2. For example, the first hole 130 may be provided by etching the lower insulating layer 112, the first substrate region 100, the first wire insulating layer 120, and a second wire insulating layer 220. The first hole 130 may expose the lower insulating layer 112, the first substrate region 100, the first wire insulating layer 120, the second wire insulating layer 220, the first to sixth horizontal wires HM1a to HM1f, and second horizontal wires 222a. The shape of the first hole 130 may be determined as needed, according to design constraints. The first hole 130 may be a region where a first via 132 is formed.

The first stacked structure S1 may include the first via 132. The first via 132 may be provided within the connection region C. The first via 132 may extend along surfaces of the lower insulating layer 112, the first substrate region 100, the first wire insulating layer 120, the second wire insulating layer 220, the horizontal wires first to sixth HM1a to HM1f, and the second horizontal wires 222a exposed by the first hole 130. The first via 132 may extend onto the lower insulating layer 112 adjacent to the first hole 130. The first via 132 may electrically connect the first wires 122 within the sensor array region SAR and second wires 222 within the connection region C. The first via 132 may transfer the charge carriers generated in the photoelectric conversion region CR to second transistors TR2. For example, the first via 132 may include, but not be limited to, electrically conductive materials (e.g., at least one of titanium (Ti), tantalum (Ta), tungsten (W), molybdenum (Mo), cobalt (Co), copper (Cu), aluminum (Al), silver (Ag), gold (Au), platinum (Pt), ruthenium (Ru), titanium nitride (TiN), tungsten nitride (WN), niobium nitride (NbN), or a combination thereof).

The first stacked structure S1 may include an insulating layer 134. The insulating layer 134 may be provided within the connection region C. The insulating layer 134 may be provided on the first via 132. The insulating layer 134 may extend along the first via 132. An end of the insulating layer 134 may be in contact with the lower insulating layer 112. The insulating layer 134 may cover the first via 132. When the first via 132 is exposed to the outside (e.g., not covered by the insulating layer 134), the first via 132 may be corroded. The insulating layer 134 may include an electrical insulating material. For example, the insulating layer 134 may include silicon-based insulating materials (e.g., at least one of silicon oxide (SiOₓ), silicon nitride (SiNₓ), and silicon oxynitride (SiOₓN_{y})) or high-k dielectric materials (e.g., metal oxides containing at least one of hafnium (Hf), zirconium (Zr), aluminum (Al), tantalum (Ta), titanium (Ti), yttrium (Y), lanthanum (La), or the like).

The first stacked structure S1 may include second holes 140. The second holes 140 may be provided within the pad region P. The second holes 140 may extend along the third direction DR3. The second holes 140 may penetrate the lower insulating layer 112, the first substrate region 100, the first wire insulating layer 120, and a portion of the second wire insulating layer 220 adjacent to the first wire insulating layer 120 to expose the second horizontal wires 222a. A shape of the second holes 140 may be determined as needed, according to design constraints. In some example embodiments, the shape of the second holes 140 may have a square pillar shape. In some other example embodiments, the shape of the second holes 140 may have a circular pillar shape, a triangular pillar shape, a rectangular pillar shape, or a cross-pillar shape. Although three (3) second holes 140 are illustrated, the present disclosure is not limited in this regard. That is, the number of second holes 140 may be determined as needed, according to design constraints. The second holes 140 may be regions where the second vias 146 are formed.

The first stacked structure S1 may include a pad groove 142. The pad groove 142 may be provided within the pad region P. The pad groove 142 may be adjacent to the second surface 100b. For example, the pad groove 142 may be formed by etching an upper portion of the first substrate region 100. The lower insulating layer 112 may be provided on the pad groove 142. As another example, the lower insulating layer 112 may extend along a surface of the substrate region 100 exposed by the pad groove 142. The pad groove 142 may be a region where a second conductive pad 148 is formed.

The first stacked structure S1 may include a first conductive pad 144. The first conductive pad 144 may be provided in the pad groove 142. The first conductive pad 144 may be provided on the lower insulating layer 112. The first conductive pad 144 may overlap the second holes 140 along the third direction DR3. For example, the first conductive pad 144 may cover the second holes 140. A top surface of the first conductive pad 144 may be positioned at a lower level than the second surface 100b. As another example, the top surface of the first conductive pad 144 may be adjacent to the first surface 100a than the second surface 100b. A sidewall of the first conductive pad 144 may be spaced apart from the lower insulating layer 112.

The second vias 146 may be provided in each of the second holes 140. The second vias 146 may be connected to the first conductive pad 144. In some example embodiments, the first conductive pad 144 and the second vias 146 may be connected to each other without an interface between them, forming a single structure. A shape of the second vias 146 may be determined as needed, according to design constraints. In some example embodiments, the shape of the second vias 146 may have a square pillar shape. In some other example embodiments, the shape of the second vias 146 may have a circular pillar shape, a triangular pillar shape, a rectangular pillar shape, a cross-pillar shape, or the like. The second vias 146 may be arranged in rows extending along the second direction DR2 and columns extending along the first direction DR1. The number of rows and columns of the second vias 146 may be determined as needed, according to design constraints. As illustrated in FIG. 4C, from a plan view, the second vias 146 may be arranged in rows extending along the second direction DR2 and the first direction DR1 on an upper and lower portion of the first conductive pad 144, respectively may be arranged in rows extending along the line. In some example embodiments, from a plan view, the second vias 146 may be arranged in three rows and one column. The number of rows and columns of the second vias 146 may be determined as needed, according to design constraints. The second vias 146 may provide low resistance to the charge carriers transferred from the second conductive pad 148 to the second horizontal wires 222a.

The first conductive pad 144 and the second vias 146 may include a material with suitable gap fill characteristics. The gap fill characteristic may be a characteristic that fills an empty space with a high aspect ratio. For example, the gap fill characteristic may be a characteristic that fills the second hole 140. As another example, the first conductive pad 144 and the second vias 146 may include, but not be limited to, electrically conductive materials. For example, the first conductive pad 144 and the second vias 146 may include, but not be limited to, tungsten (W).

The first stacked structure S1 may include the second conductive pad 148. The second conductive pad 148 may be provided within the pad region P. As illustrated in FIG. 4C, the second conductive pad 148 may be surrounded by the lower insulating layer 112. From a plan view, the first conductive pad 144 may have a smaller size than a size of the second conductive pad 148. The second conductive pad 148 may cover the first conductive pad 144. The second conductive pad 148 may extend to a region between the sidewall of the first conductive pad 144 and the lower insulating layer 112. The second conductive pad 148 may be in contact with the first conductive pad 144 and the lower insulating layer 112 between the sidewall of the first conductive pad 144 and the lower insulating layer 112. The second conductive pad 148 may fill the pad groove 142. A top surface of the second conductive pad 148 may be positioned at the same or lower level than the second surface 100b. The second conductive pad 148 may be electrically connected to the first conductive pad 144, the second vias 146, the second wires 222 within the pad region P and the second transistors TR2.

In some example embodiments, a process of forming the color filters 116 may include applying a color resin solution on the lower insulating layer 112 and curing the applied color resin solution. For example, applying the color resin solution may be performed by a spin coating process. When the top surface of the second conductive pad 148 is provided at a higher level than the second surface 100b, the second conductive pad 148 protruding onto a top surface of the lower insulating layer 112 and layers formed on the second conductive pad 148 may interfere with the flow of the color resin solution during the application process. For example, the color resin coating may have a wave pattern due to the second conductive pad 148 protruding onto the top surface of the lower insulating layer 112 and the layers formed on the second conductive pad 148. Accordingly, the color filters 116 may not be able to achieve a needed quality level, according to design constraints.

In the present disclosure, the second conductive pad 148 may not protrude onto the lower insulating layer 112 provided on the second surface 100b. Accordingly, the second conductive pad 148 and the layers formed on the second conductive pad 148 may not impede the flow of the color resin solution. As a result, the color resin solution may be evenly applied on the lower insulating layer 112. Accordingly, the color filters 116 may be able to achieve the needed quality level, according to the design constraints.

The second stacked structure S2 may include a second substrate region 200. The second substrate region 200 may be provided within the sensor array region SAR, the connection region C, and the pad region P. The second substrate region 200 may include a semiconductor material. For example, the second substrate region 200 may include silicon (Si), germanium (Ge), or silicon-germanium (Si—Ge). For example, the second substrate region 200 may have the first conductivity type. The second substrate region 200 may be an epitaxial layer formed by the epitaxial growth process. The crystal structure of the second substrate region 200 may include at least one of a single-crystalline structure, a polycrystalline structure, or an amorphous structure. The second substrate region 200 may include a third surface 200a and a fourth surface 200b facing opposite directions. The third surface 200a and the fourth surface 200b may extend along the first direction DR1 and the second direction DR2. The third surface 200a may be spaced apart from the fourth surface 200b along the third direction DR3.

The second stacked structure S2 may include the second wire insulating layer 220. The second wire insulating layer 220 may be provided within the sensor array region SAR, the connection region C, and the pad region P. The second wire insulating layer 220 may be provided on the third surface 200a. The second wire insulating layer 220 may be provided between the first wire insulating layer 120 and the second substrate region 200. In some example embodiments, the second wire insulating layer 220 may have a single-layer structure. In some other example embodiments, the second wire insulating layer 220 may have a multi-layer structure. For example, the second wire insulating layer 220 may include an electrical insulating material. As another example, the electrical insulating material may include at least one of silicon oxide (SiOₓ), silicon nitride (SiNₓ), silicon oxynitride (SiOₓN_{y}), germanium oxide (GeOₓ), germanium nitride (GeNₓ), germanium oxynitride (GeOₓN_{y}), or a combination thereof.

The second stacked structure S2 may include the second wires 222. The second wires 222 may be provided within the sensor array region SAR, the connection region C, and the pad region P. The second wires 222 may be provided in the second wire insulating layer 220. The second wires 222 may include second horizontal wires 220a and second vertical wires 222b. The second horizontal wires 220a may extend along the direction parallel to the first surface 100a (e.g., the first direction DR1, second direction DR2, or the combined direction of the first direction DR1 and the second direction DR2). The second vertical wires 222b may extend along the direction perpendicular to the first surface 100a (e.g., the third direction DR3). However, the present disclosure is not limited in this regard. For example, the shape and the number of the second wires 222 may be appropriately determined as needed, according to design constraints. The second wires 222 may provide electrical connections between the first via 132 and other electrical components. The second wires 222 may provide electrical connections between the first conductive pad 144, the second vias 146, and other electrical components. In some example embodiments, the second wires 222 may include, but not be limited to, electrically conductive materials. For example, the electrically conductive materials may include, but not be limited to, at least one of titanium (Ti), tantalum (Ta), tungsten (W), molybdenum (Mo), cobalt (Co), copper (Cu), aluminum (Al), silver (Ag), gold (Au), platinum (Pt), ruthenium (Ru), titanium nitride (TiN), tungsten nitride (WN), niobium nitride (NbN), or the like. The second wires 222 may be electrically connected to at least one of the transmission gate, the source follower gate, the reset gate, and the selection gate. For example, the second wires 222 may be configured to apply the power supply voltage VDD to the drain of the reset transistor RX or the drain of the source follower transistor DX.

The second stacked structure S2 may include the second transistors TR2. The second transistors TR2 may be provided within the connection region C and the pad region P. In some example embodiments, the second transistors TR2 may be provided on the third surface 200a of the second substrate region 200. The second transistors TR2 may be provided to output the electrical signal transmitted from the selection transistor to the outside.

The second transistors TR2 may include the gate electrodes. In some example embodiments, the gate electrodes may include, but not be limited to, electrically conductive materials. For example, the gate electrodes may include, but not be limited to, polysilicon (e.g., doped polysilicon), metal silicide, or metal (e.g., at least one of titanium (Ti), tantalum (Ta), tungsten (W), molybdenum (Mo), cobalt (Co), copper (Cu), aluminum (Al), silver (Ag), gold (Au), platinum (Pt), ruthenium (Ru), titanium nitride (TiN), tungsten nitride (WN), niobium nitride (NbN), or a combination thereof).

The second transistors TR2 may include the gate insulating layers. For example, the gate insulating layers may be provided between the gate electrodes and the third surface 200a of the second substrate region 200. In some example embodiments, the gate insulating layers may extend along surfaces of the gate electrodes facing the third surface 200a to electrically separate the gate electrodes from the second substrate region 200. For example, the gate insulating layers may include, but not be limited to, silicon-based insulating materials (e.g., at least one of silicon oxide (SiOₓ), silicon nitride (SiNₓ), and silicon oxynitride (SiOₓN_{y})) or high-k dielectric materials (e.g., metal oxides containing at least one of hafnium (Hf), zirconium (Zr), aluminum (Al), tantalum (Ta), titanium (Ti), yttrium (Y), lanthanum (La), or the like).

The second transistors TR2 may include gate spacers. For example, the gate spacers may be provided on sidewalls of the gate electrodes. In some example embodiments, the gate spacers may be configured to electrically separate the gate electrodes from adjacent components (e.g., the second wire insulating layer 220). For example, the gate spacers may include, but not be limited to, electrically insulating materials (e.g., at least one of silicon nitride (SiNₓ), silicon carbide nitride (SiCₓN_{y}), or silicon oxynitride (SiOₓN_{y})).

A plurality of second vias 146 may be provided to have low resistance when the charge carriers are transferred from the second conductive pad 148 to the second horizontal wires 222a.

According to some example embodiments of the present disclosure, the first conductive pad 144 and the second vias 146 may be provided in a lower portion of the second conductive pad 148. Additionally, the top surface of the second conductive pad 148 may be provided to be equal to or lower than the second surface 100b of the first substrate region 100. Accordingly, when forming the color filters 116, manufacturing defects of the color filters 116 may be reduced.

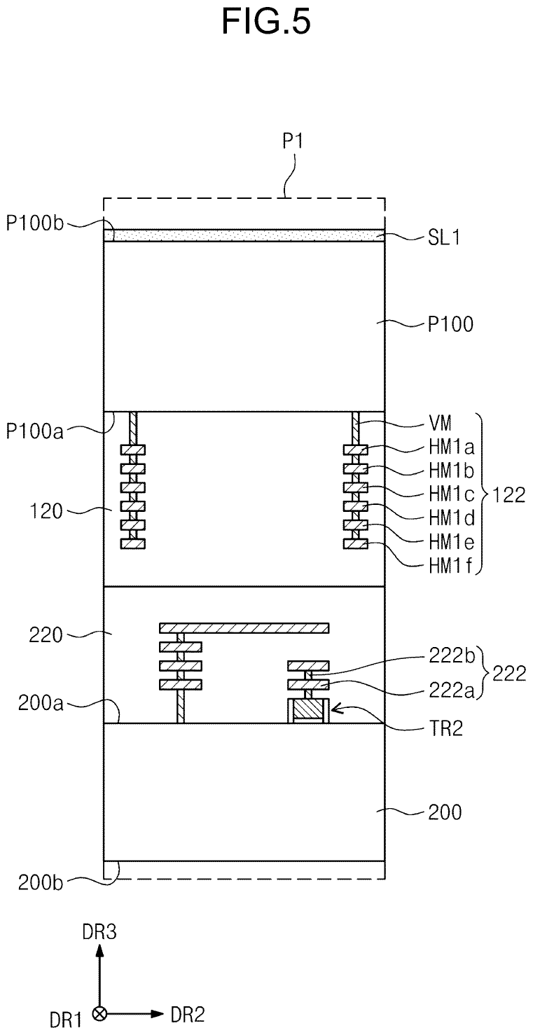

FIGS. 5 to 11 are cross-sectional views corresponding to line A-A′ in FIG. 4B of a method of manufacturing an image sensor, according to some example embodiments. The image sensor depicted in FIGS. 5 to 11 may include and/or may be similar in many respects to the image sensor described above with reference to FIGS. 4A, 4B, and 4C, and may include additional features not mentioned above. Consequently, repeated descriptions of the image sensor described above with reference to FIGS. 4A, 4B, and 4C may be omitted for the sake of brevity.

Referring to FIG. 5, the second substrate region 200, the second wire insulating layer 220, the first wire insulating layer 120, and the first substrate region 100 may be sequentially formed along the third direction DR3. The first wires 122 may be formed in the first wire insulating layer 120. The second wires 222 and the second transistors TR2 may be formed in the second wire insulating layer 220. The first substrate region 100, the second substrate region 200, the first wire insulating layer 120, the second wire insulating layer 220, the first wires 122, the second wires 222, and the second transistors TR2 are described with reference to FIGS. 4A, 4B, and 4C.

A first sacrificial layer SL1 may be formed on the first preliminary substrate region P100. A first preliminary substrate region P100 may include a first surface P100a and a second surface P100b facing opposite directions. The first surface P100a and the second surface P100b may extend along the first direction DR1 and the second direction DR2. The first surface P100a may be spaced apart from the second surface P100b along the third direction DR3. The first sacrificial layer SL1 may be configured along a direction parallel to the second surface P100b (e.g., the first direction DR1, the second direction DR2, or a combined direction of the first direction DR1 and the second direction DR2) of the first preliminary substrate region P100. For example, the first sacrificial layer SL1 may include photoresist. The first sacrificial layer SL1 may be formed by a coating process. For example, the coating process may be performed using a spin-coating method, a spray-coating method, a dip-coating method, an inkjet printing method, or a slot-die coating method.

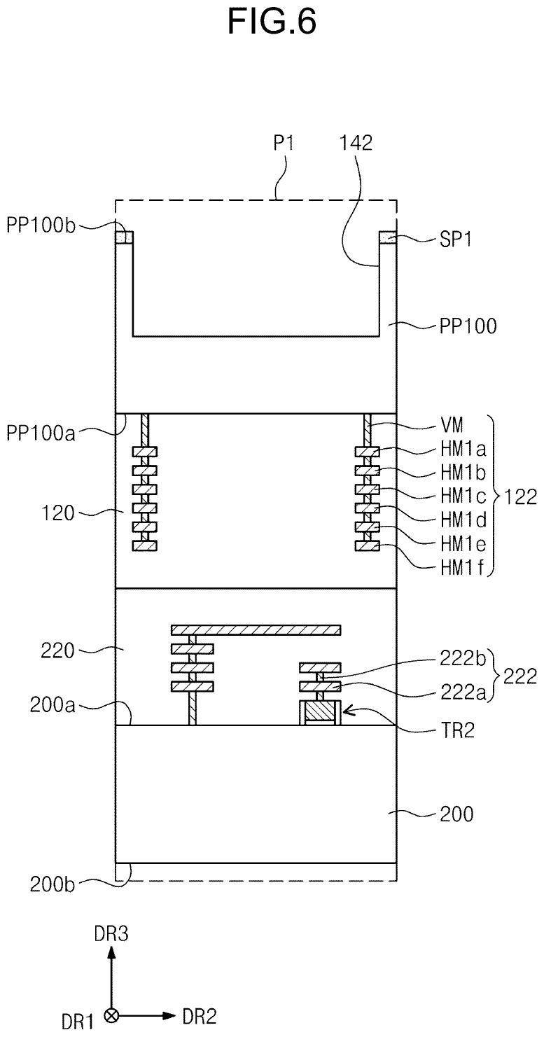

Referring to FIG. 6, the first sacrificial layer SL1 may be patterned to form first sacrificial patterns SP1. Forming the first sacrificial patterns SP1 may include an exposure process of irradiating light to a required region of the first sacrificial layer SL1 and a development process of removing either the exposed portion or the unexposed portion. The first sacrificial patterns SP1 may be spaced apart from each other. The first preliminary substrate region P100 may be exposed between the first sacrificial patterns SP1.

The first preliminary substrate region P100 may be etched to form a second preliminary substrate region PP100. Forming the second preliminary substrate region PP100 may include an etching process using the first sacrificial patterns SP1 provided on the first preliminary substrate region P100. The pad groove 142 may be formed by a process of forming the second preliminary substrate region PP100. The first sacrificial patterns SP1 may be removed during or after the etching process. For example, the etching process may be performed using a dry etching process or a wet etching process.

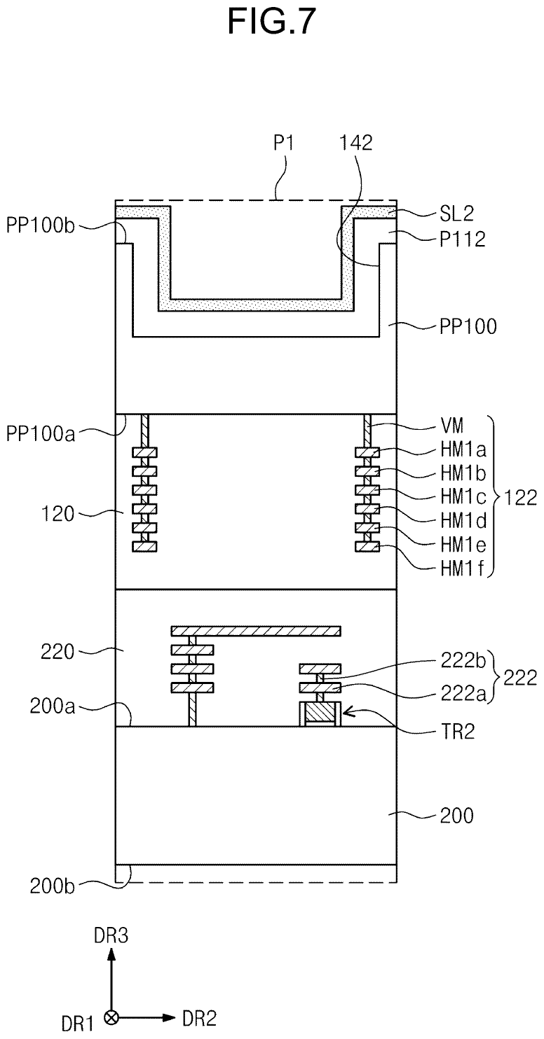

Referring to FIG. 7, a preliminary lower insulating layer P112 may be formed on the second preliminary substrate region PP100. The preliminary lower insulating layer P112 may extend along a surface of the second preliminary substrate region PP100. At least a portion of the second preliminary substrate region PP100 may be provided in the pad groove 142. For example, forming the preliminary lower insulating layer P112 may be performed using a physical vapor deposition (PVD) process, a chemical vapor deposition (CVD) process, or an atomic layer deposition (ALD) process.

A second sacrificial layer SL2 may be formed on the preliminary lower insulating layer P112. For example, the second sacrificial layer SL2 may include photoresist. The second sacrificial layer SL2 may be formed by a coating process. For example, the coating process may be performed using a spin-coating method, a spray-coating method, a dip-coating method, an inkjet printing method, or a slot-die coating method.

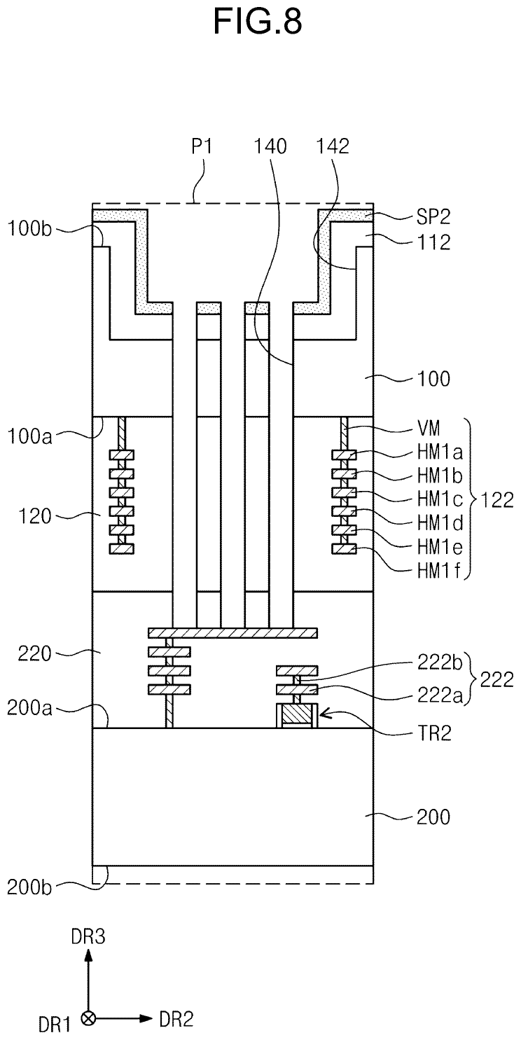

Referring to FIG. 8, the second sacrificial layer SL2 may be patterned to form second sacrificial patterns SP2. Forming the second sacrificial patterns SP2 may include an exposure process of irradiating light to a required region of the second sacrificial layer SL2 and a development process of removing either the exposed portion or the non-exposed portion. The second sacrificial patterns SP2 may be spaced apart from each other. The preliminary lower insulating layer P112 may be exposed between the second sacrificial patterns SP2.

The preliminary lower insulating layer P112, the second preliminary substrate region PP100, the first wire insulating layer 120, and the second preliminary wire insulating layer P220 may be etched to form the second holes 140. Forming the second holes 140 may include an etching process using the second sacrificial patterns SP2 provided on the preliminary lower insulating layer P112. The second sacrificial patterns SP2 may be removed during the etching process or after the etching process is completed. For example, the etching process may be performed using a dry etching process or a wet etching process.

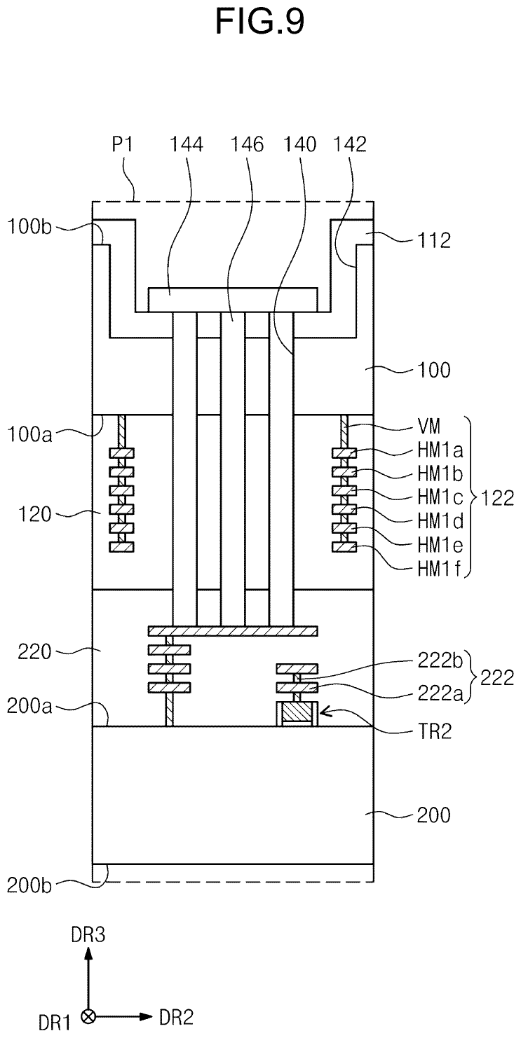

Referring to FIG. 9, the first conductive pad 144 and the second vias 146 may be formed. Forming the first conductive pad 144 and the second vias 146 may include forming a first preliminary conductive layer covering the lower insulating layer 112 and filling the second hole 140 and patterning the first preliminary conductive layer. In some example embodiments, forming the first preliminary conductive layer may include depositing a conductive material. For example, depositing the conductive material may be performed using a physical vapor deposition (PVD) process, a chemical vapor deposition (CVD) process, or an atomic layer deposition (ALD) process.

Patterning the first preliminary conductive layer may be performed by an etching process using a sacrificial pattern formed on the first preliminary conductive layer as an etch mask. For example, the sacrificial pattern may be formed by irradiating light to a required region of the photoresist layer and removing either the exposed portion or the unexposed portion. The sacrificial pattern may expose the first preliminary conductive layer. The sacrificial patterns may be removed during or after the etching process. For example, the etching process may be performed using a dry etching process or a wet etching process. In the patterning process of the first preliminary conductive layer, a region adjacent to a sidewall of the first preliminary conductive layer may be removed. Accordingly, the sidewall of the first conductive pad 144 may be spaced apart from the lower insulating layer 112. In some example embodiments, the sidewall of the first conductive pad 144 and the lower insulating layer 112 may be provided directly adjacent to each other.

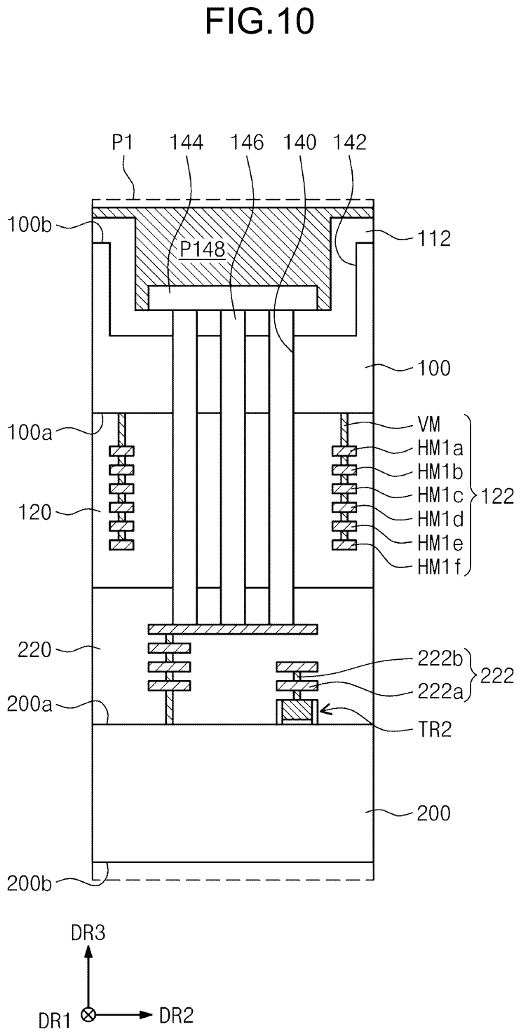

Referring to FIG. 10, a second preliminary conductive pad P148 may be formed to cover the lower insulating layer 112 and the first conductive pad 144. The second preliminary conductive pad P148 may fill a region between the sidewall of the first conductive pad 144 and the lower insulating layer 112. For example, forming the second preliminary conductive pad P148 may be performed using a physical vapor deposition (PVD) process, a chemical vapor deposition (CVD) process, or an atomic layer deposition (ALD) process.

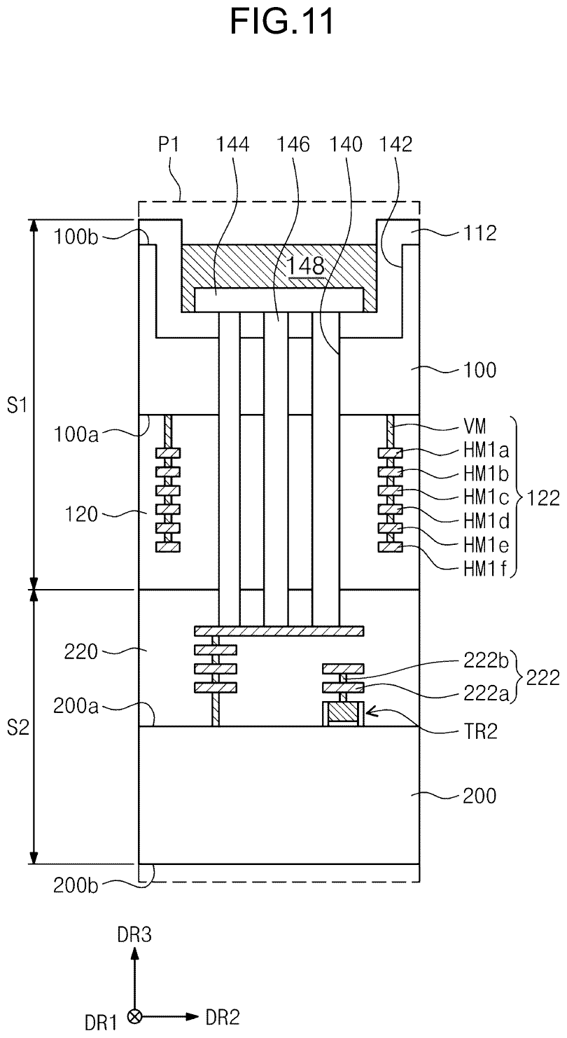

Referring to FIG. 11, the second preliminary conductive pad P148 may be etched to form the second conductive pad 148. Forming the second conductive pad 148 may include an etching process. For example, the second preliminary conductive pad P148 may be formed by an etching process using an etchant or an etchant gas having a high etch selectivity with respect to the lower insulating layer 112.

The second conductive pad 148 may be formed on the first conductive pad 144. The second conductive pad 148 may be formed in the pad groove 142. The second conductive pad 148 may be formed to cover the first conductive pad 144. The second conductive pad 148 may fill the region between the sidewall of the first conductive pad 144 and the lower insulating layer 112. A top surface of the second conductive pad 148 may be positioned at a level equal to or lower than a top surface of the lower insulating layer 112 provided on the second surface 100b.

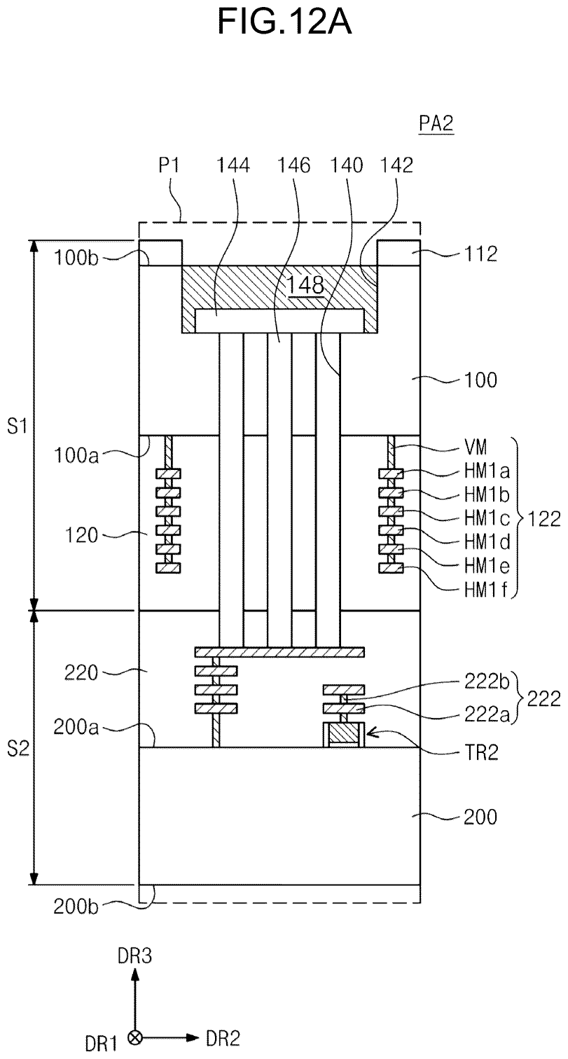

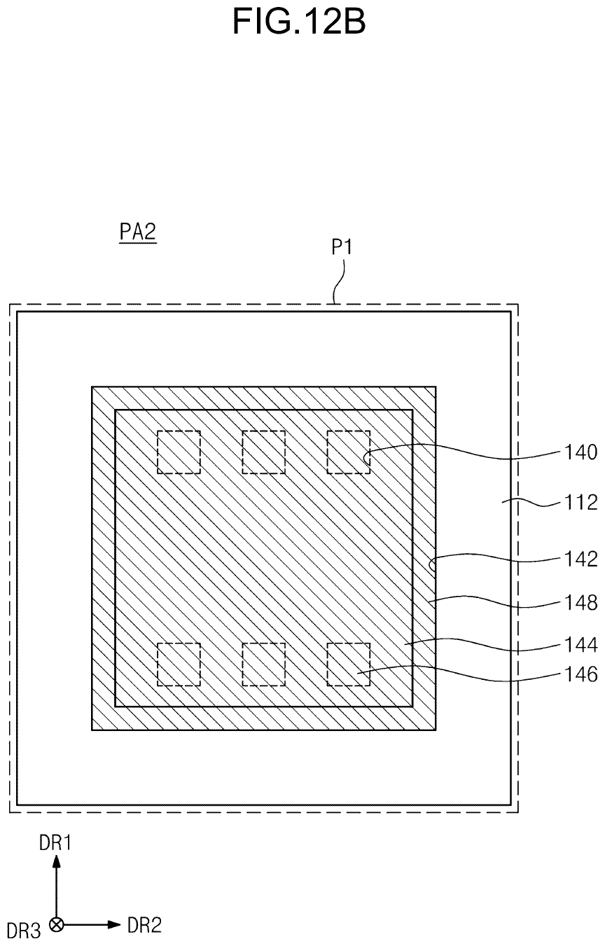

FIG. 12A is a cross-sectional view illustrating an image sensor, according to some example embodiments. FIG. 12B is a plan view of the image sensor of FIG. 12A, according to some example embodiments. The image sensor depicted in FIGS. 12A and 12B may include and/or may be similar in many respects to the image sensor described above with reference to FIGS. 4A, 4B, and 4C, and may include additional features not mentioned above. Consequently, repeated descriptions of the image sensor described above with reference to FIGS. 4A, 4B, and 4C may be omitted for the sake of brevity.

Referring to FIGS. 12A and 12B, an image sensor PA2 may be provided. In some example embodiments, the second conductive pad 148 may be provided between the lower insulating layers 112. As illustrated in FIG. 12B, from a plan view, the second conductive pad 148 may be provided corresponding to the pad groove 142.

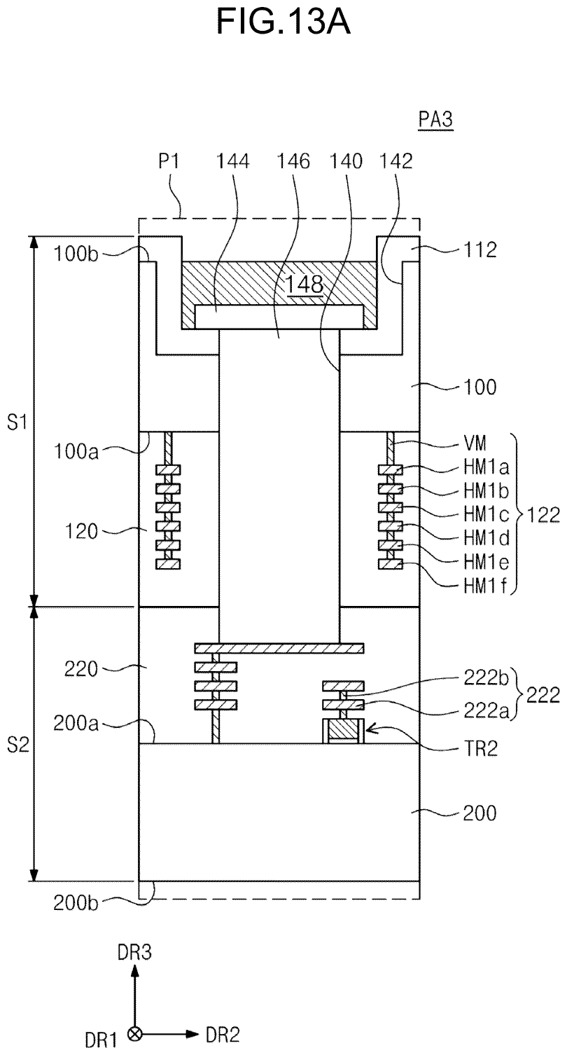

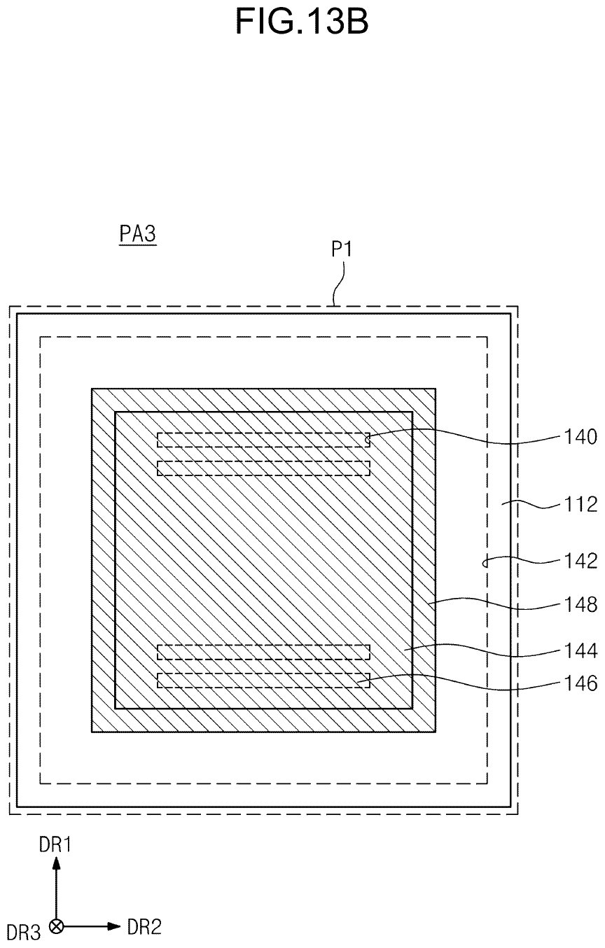

FIG. 13A is a cross-sectional view illustrating an image sensor, according to some example embodiments. FIG. 13B is a plan view the image sensor of FIG. 13A. The image sensor depicted in FIGS. 13A and 13B may include and/or may be similar in many respects to the image sensor described above with reference to FIGS. 4A, 4B, and 4C, and may include additional features not mentioned above. Consequently, repeated descriptions of the image sensor described above with reference to FIGS. 4A, 4B, and 4C may be omitted for the sake of brevity.

Referring to FIGS. 13A and 13B, an image sensor PA3 may be provided. In some example embodiments, from a plan view, a shape of the second holes 140 and the second vias 146 may have a line shape extending along the second direction DR2. From a plan view, the second conductive pad 148 may be provided to be surrounded by the lower insulating layer 112. From a plan view, a width of the first conductive pad 144 may be smaller than that of the second conductive pad 148. The first conductive pad 144 and the second conductive pad 148 may overlap along the third direction DR3.

From a plan view, widths of the second vias 146 may be provided to be smaller than the width of the first conductive pad 144. The widths of the second vias 146 may be the size of the second vias 146 along the second direction DR2. From a plan view, heights of the second vias 146 may be provided to be smaller than a height of the first conductive pad 144. The heights of the second vias 146 may be the size of the second vias 146 along the first direction DR1. The first conductive pad 144 and the second vias 146 may overlap along the third direction DR3.

As illustrated in FIG. 13B, the second vias 146 may be arranged in rows extending along the first direction DR1 on an upper and lower portion of the first conductive pad 144, respectively. In some example embodiments, from a plan view, the second vias 146 may be arranged in two (2) rows. However, the present disclosure is not limited in this regard. That is, the number of rows of the second vias 146 may be determined as needed, according to design constraints. The second vias 146 may be provided to have low resistance when the charge carriers (e.g., electrons or holes) are transferred from the second conductive pad 148 to the second horizontal wires 222a.

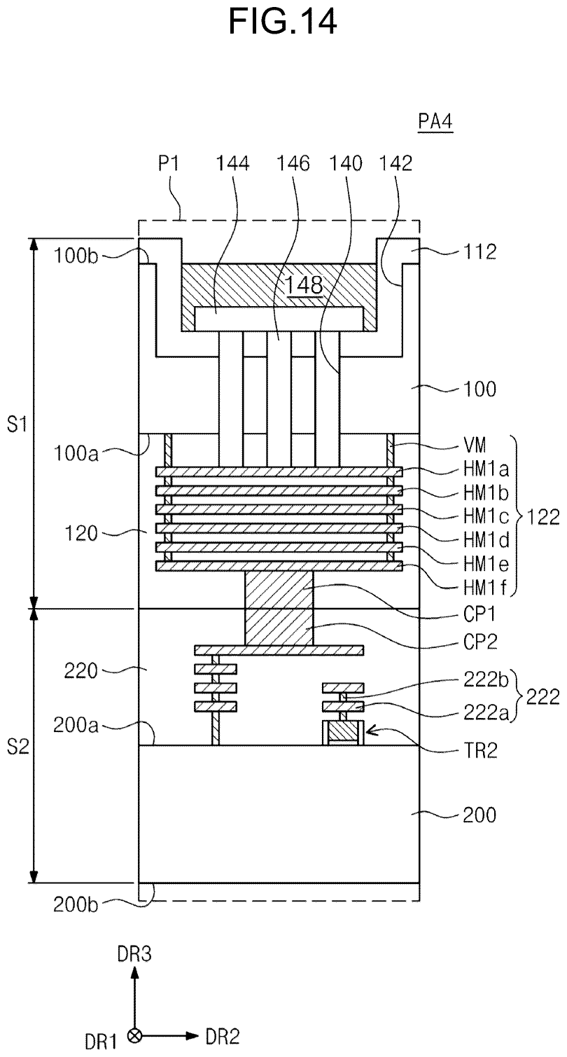

FIG. 14 is a cross-sectional view illustrating an image sensor, according to some example embodiments. The image sensor depicted in FIG. 14 may include and/or may be similar in many respects to the image sensor described above with reference to FIGS. 4A, 4B, 4C, and 12B, and may include additional features not mentioned above. Consequently, repeated descriptions of the image sensor described above with reference to FIGS. 4A, 4B, 4C, and 12B may be omitted for the sake of brevity.

Referring to FIG. 14, an image sensor PA4 may be provided. In some example embodiments, the first wires 122 may be provided. The first wires 122 may include the first horizontal wire HM1a, the second horizontal wire HM1b, the third horizontal wire HM1c, the fourth horizontal wire HM1d, the fifth horizontal wire HM1e, the sixth horizontal wire HM1f, and the first vertical wires VM. For example, the first to sixth horizontal wires HM1a to HM1f may be provided along a direction parallel to the first surface 100a (e.g., the first direction DR1, the second direction DR2, or a combined direction of the first direction DR1 and the second direction DR2). As another example, the second vias 146 may be provided to be electrically connected to the first horizontal wire HM1a.

A first connection pad CP1 and a second connection pad CP2 may be provided to electrically connect the first stacked structure S1 and the second stacked structure S2. The first connection pad CP1 and the second connection pad CP2 may be in contact with each other. The first connection pad CP1 may be provided in a lower portion of the first wire insulating layer 120. The first connection pad CP1 may be electrically connected to the sixth horizontal wire HM1f. The first connection pad CP1 may penetrate the first wire insulating layer 120 between the sixth horizontal wire HM1f and the second wire insulating layer 220. The second connection pad CP2 may be provided on an upper portion of the second wire insulating layer 220. The second connection pad CP2 may be electrically connected to the second horizontal wires 222a closest to the first wire insulating layer 120. The second connection pad CP2 may penetrate the second wire insulating layer 220 between the first wire insulating layer 120 and the second horizontal wires 222a closest to the first wire insulating layer 120. For example, the first and second connection pads CP1 and CP2 may include, but not be limited to, electrically conductive materials (e.g., copper (Cu)).

The second vias 146 of FIG. 14 may include and/or may be substantially similar in many respects to the second vias 146 described above with reference to FIG. 12B.

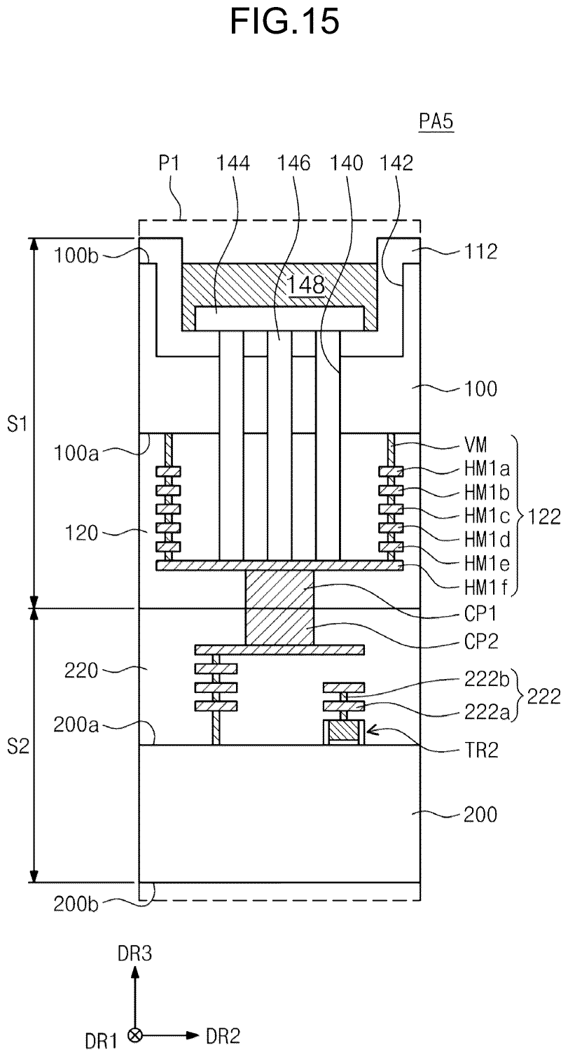

FIG. 15 is a cross-sectional view illustrating an image sensor, according to some example embodiments. The image sensor depicted in FIG. 15 may include and/or may be similar in many respects to the image sensor described above with reference to FIGS. 4A, 4B, 4C, and 12B, and may include additional features not mentioned above. Consequently, repeated descriptions of the image sensor described above with reference to FIGS. 4A, 4B, 4C, and 12B may be omitted for the sake of brevity.

Referring to FIG. 15, an image sensor PA5 may be provided. In some example embodiments, the first wires 122 may be provided. The first wires 122 may include the first horizontal wire HM1a, the second horizontal wire HM1b, the third horizontal wire HM1c, the fourth horizontal wire HM1d, the fifth horizontal wire HM1e, the sixth horizontal wire HM1f, and the first vertical wires VM. For example, the first to fifth horizontal wires HM1a to HM1e may be provided to surround the second vias 146 from a plan view. As another example, the sixth horizontal wire HM1f may be provided along a direction parallel to the first surface 100a (e.g., the first direction DR1, the second direction DR2, or a combined direction of the first direction DR1 and the second direction DR2). In some example embodiments, the second vias 146 may be provided to be connected to the sixth horizontal wire HM1f. In some example embodiments, the number of horizontal wires provided in the direction parallel to the first surface 100a may be determined as needed, according to design constraints. The number of horizontal wires provided to surround the second vias 146 may be determined as needed, according to design constraints. For example, the first and second horizontal wires HM1a and HM1b may surround the second vias 146, and the second vias 146 may be provided to be electrically connected to the third horizontal wire HM1c. For example, the first to third horizontal wires HM1a to HM1c may be provided to surround the second vias 146, and the second vias 146 may be electrically connected to the fourth horizontal wire HM1d. As another example, the first to fourth horizontal wires HM1a to HM1d may be provided to surround the second vias 146, and the second vias 146 may be electrically connected to the fifth horizontal wire HM1e.

The first connection pad CP1 and the second connection pad CP2 may be provided to electrically connect the first stacked structure S1 and the second stacked structure S2. The first connection pad CP1 and the second connection pad CP2 may be in contact with each other. The first connection pad CP1 may be provided in a lower portion of the first wire insulating layer 120. The first connection pad CP1 may be electrically connected to the sixth horizontal wire HM1f. The first connection pad CP1 may penetrate the first wire insulating layer 120 between the sixth horizontal wire HM1f and the second wire insulating layer 220. The second connection pad CP2 may be provided on an upper portion of the second wire insulating layer 220. The second connection pad CP2 may be electrically connected to the second horizontal wires 222a closest to the first wire insulating layer 120. The second connection pad CP2 may penetrate the second wire insulating layer 220 between the first wire insulating layer 120 and the second horizontal wires 222a closest to the first wire insulating layer 120. For example, the first and second connection pads CP1 and CP2 may include, but not be limited to, electrically conductive materials (e.g., copper (Cu)).

The second vias 146 of FIG. 15 may include and/or may be substantially similar in many respects to the second vias 146 described above with reference to FIG. 12B.

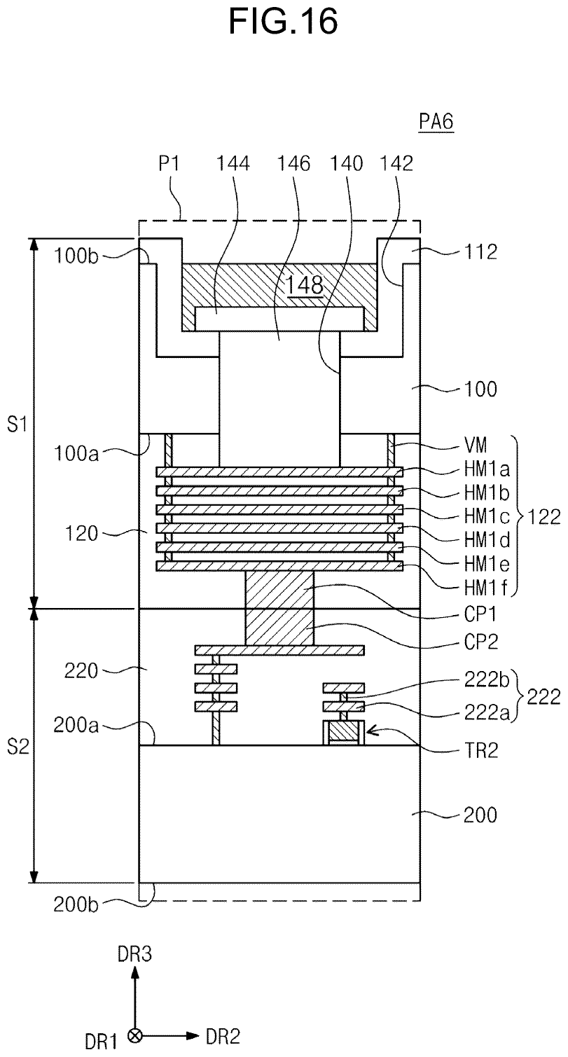

FIG. 16 is a cross-sectional view illustrating an image sensor, according to some example embodiments. The image sensor depicted in FIG. 16 may include and/or may be similar in many respects to the image sensor described above with reference to FIGS. 4A, 4B, and 4C, and may include additional features not mentioned above. Consequently, repeated descriptions of the image sensor described above with reference to FIGS. 4A, 4B, and 4C may be omitted for the sake of brevity.

Referring to FIG. 16, an image sensor PA6 may be provided. In some example embodiments, from a plan view, a shape of the second holes 140 and the second vias 146 may have a line shape extending along the second direction DR2.

The first wires 122 may be provided. The first wires 122 may include the first horizontal wire HM1a, the second horizontal wire HM1b, the third horizontal wire HM1c, the fourth horizontal wire HM1d, the fifth horizontal wire HM1e, the sixth horizontal wire HM1f, and the first vertical wires VM. For example, first to sixth horizontal wires HM1a to HM1f may be provided along a direction parallel to the first surface 100a (e.g., the first direction DR1, the second direction DR2, or a combined direction of the first direction DR1 and the second direction DR2). As another example, the second vias 146 may be provided to be electrically connected to the first horizontal wire HM1a.

The first connection pad CP1 and the second connection pad CP2 may be provided to electrically connect the first stacked structure S1 and the second stacked structure S2. The first connection pad CP1 and the second connection pad CP2 may be in contact with each other. The first connection pad CP1 may be provided in a lower portion of the first wire insulating layer 120. The first connection pad CP1 may be electrically connected to the sixth horizontal wire HM1f. The first connection pad CP1 may penetrate the first wire insulating layer 120 between the sixth horizontal wire HM1f and the second wire insulating layer 220. The second connection pad CP2 may be provided on an upper portion of the second wire insulating layer 220. The second connection pad CP2 may be electrically connected to the second horizontal wires 222a closest to the first wire insulating layer 120. The second connection pad CP2 may penetrate the second wire insulating layer 220 between the first wire insulating layer 120 and the second horizontal wires 222a closest to the first wire insulating layer 120. For example, the first and second connection pads CP1 and CP2 may include, but not be limited to, electrically conductive materials (e.g., copper (Cu)).

The second vias 146 of FIG. 16 may include and/or may be substantially similar in many respects to the second vias 146 described above with reference to FIG. 13B.

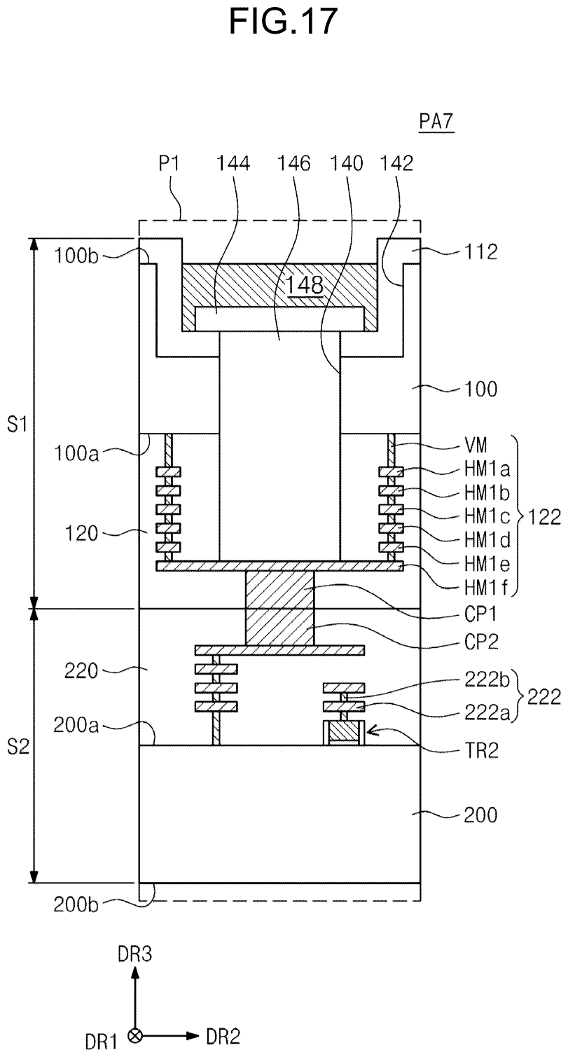

FIG. 17 is a cross-sectional view illustrating an image sensor, according to some example embodiments. The image sensor depicted in FIG. 17 may include and/or may be similar in many respects to the image sensor described above with reference to FIGS. 4A, 4B, 4C, and 13B, and may include additional features not mentioned above. Consequently, repeated descriptions of the image sensor described above with reference to FIGS. 4A, 4B, 4C, and 13B may be omitted for the sake of brevity.

Referring to FIG. 17, an image sensor PA7 may be provided. In some example embodiments, from a plan view, a shape of the second holes 140 and the second vias 146 may have a line shape extending along the second direction DR2.

The first wires 122 may be provided. The first wires 122 may include the first horizontal wire HM1a, the second horizontal wire HM1b, the third horizontal wire HM1c, the fourth horizontal wire HM1d, the fifth horizontal wire HM1e, the sixth horizontal wire HM1f, and the first vertical wires VM. For example, the first to fifth horizontal wires HM1a to HM1e may be provided to surround the second vias 146 from a plan view. As another example, the sixth horizontal wire HM1f may be provided along a direction parallel to the first surface 100a (e.g., the first direction DR1, the second direction DR2, or a combined direction of the first direction DR1 and the second direction DR2). In some example embodiments, the second vias 146 may be provided to be connected to the sixth horizontal wire HM1f. In some example embodiments, the number of horizontal wires provided in the direction parallel to the first surface 100a may be determined as needed, according to design constraints. The number of horizontal wires provided to surround the second vias 146 may be determined as needed, according to design constraints. For example, the first and second horizontal wires HM1a and HM1b may surround the second vias 146, and the second vias 146 may be provided to be electrically connected to the third horizontal wire HM1c. As another example, the first to third horizontal wires HM1a to HM1c may be provided to surround the second vias 146, and the second vias 146 may be electrically connected to the fourth horizontal wire HM1d. As another example, the first to fourth horizontal wires HM1a to HM1d may be provided to surround the second vias 146, and the second vias 146 may be electrically connected to the fifth horizontal wire HM1e.

The first connection pad CP1 and the second connection pad CP2 may be provided to electrically connect the first stacked structure S1 and the second stacked structure S2. The first connection pad CP1 and the second connection pad CP2 may be in contact with each other. The first connection pad CP1 may be provided in a lower portion of the first wire insulating layer 120. The first connection pad CP1 may be electrically connected to the sixth horizontal wire HM1f. The first connection pad CP1 may penetrate the first wire insulating layer 120 between the sixth horizontal wire HM1f and the second wire insulating layer 220. The second connection pad CP2 may be provided on an upper portion of the second wire insulating layer 220. The second connection pad CP2 may be electrically connected to the second horizontal wires 222a closest to the first wire insulating layer 120. The second connection pad CP2 may penetrate the second wire insulating layer 220 between the first wire insulating layer 120 and the second horizontal wires 222a closest to the first wire insulating layer 120. For example, the first and second connection pads CP1 and CP2 may include, but not be limited to, electrically conductive materials (e.g., copper (Cu)).

The second vias 146 of FIG. 17 may include and/or may be substantially similar in many respects to the second vias 146 described above with reference to FIG. 13B.

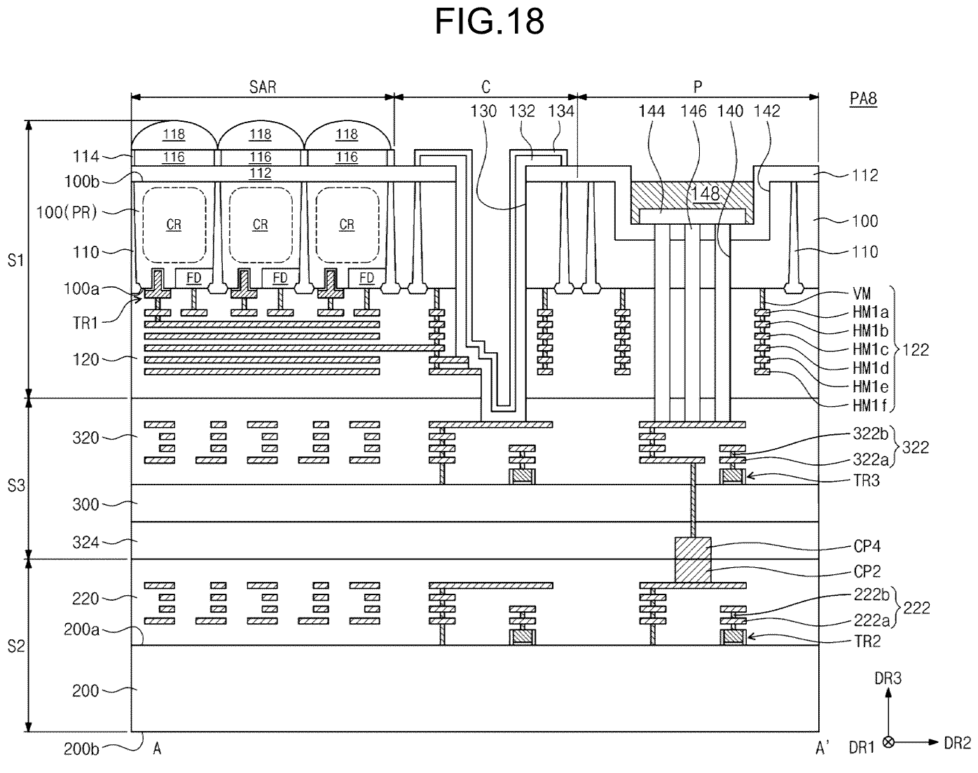

FIG. 18 is a cross-sectional view illustrating an image sensor, according to some example embodiments. The image sensor depicted in FIG. 18 may include and/or may be similar in many respects to the image sensor described above with reference to FIGS. 4A, 4B, and 4C, and may include additional features not mentioned above. Consequently, repeated descriptions of the image sensor described above with reference to FIGS. 4A, 4B, and 4C may be omitted for the sake of brevity.

Referring to FIG. 18, an image sensor PA8 may be provided. In some example embodiments, a third stacked structure S3 may be provided. The third stacked structure S3 may include a third substrate region 300, a third upper wire insulating layer 320, third wires 322, a third lower wire insulating layer 324, a fourth connection pad CP4, and third transistors TR3. Each of the third substrate region 300, the third wires 322, and the third transistors TR3 may include and/or may be substantially similar in many respects to the second substrate region 200, the second wires 222, and the second transistors TR2. The third upper wire insulating layer 320 and the third lower wire insulating layer 324 may include and/or may be substantially similar in many respects to the second wire insulating layer 220. The fourth connection pad CP4 may extend from a bottom surface of the third substrate region 300 along the third direction DR3. The fourth connection pad CP4 may include, but not be limited to, electrically conductive materials (e.g., copper (Cu)).

The third wires 322 may be provided within the sensor array region SAR, the connection region C, and the pad region P. The third wires 322 may be provided in the third upper wire insulating layer 320. The third wires 322 may be electrically connected to the fourth connection pad CP4. The fourth connection pad CP4 may be provided within the pad region P. The third transistors TR3 may be provided within the connection region C and the pad region P. The illustrated positions of the third wires 322, the fourth connection pad CP4, and the third transistors TR3 are exemplary. That is, the present disclosure is not limited in this regard. The positions of the third wires 322, the fourth connection pad CP4, and the third transistors TR3 may be determined as needed, according to design constraints. The shapes and numbers of the illustrated third wires 322 and the fourth connection pad CP4 are exemplary. That is, the present disclosure is not limited in this regard. The shape and number of the third wires 322 and the fourth connection pad CP4 may be appropriately determined as needed, according to design constraints. The number of third transistors TR3 is exemplary. That is, the present disclosure is not limited in this regard. The number of third transistors TR3 may be appropriately determined as needed, according to design constraints.

The third stacked structure S3 may be provided between the first stacked structure S1 and the second stacked structure S2. The second stacked structure S2, the third stacked structure S3, and the first stacked structure S1 may be provided sequentially along the third direction DR3. In some example embodiments, the first conductive pad 144 and the second vias 146 may be provided to electrically connect the first and second stacked structures S1 and S2. For example, the fourth connection pad CP4 may be provided on the second connection pad CP2. The second and fourth connection pads CP2 and CP4 may be provided to electrically connect the second and third stacked structures S2 and S3.

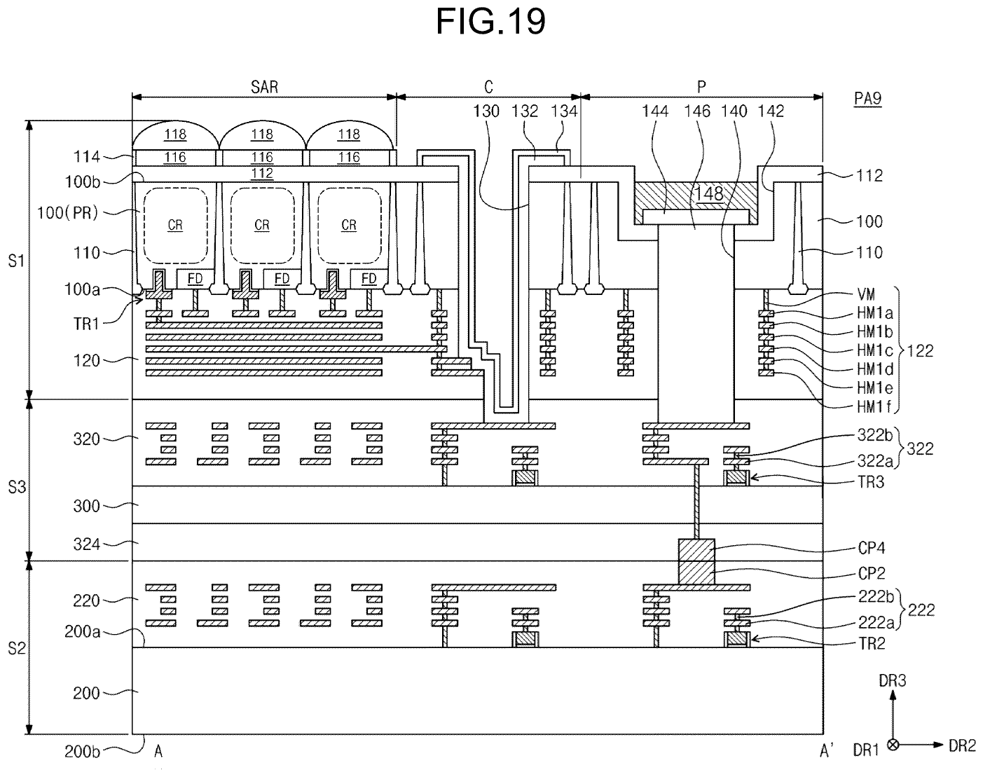

FIG. 19 is a cross-sectional view illustrating an image sensor, according to some example embodiments. The image sensor depicted in FIG. 19 may include and/or may be similar in many respects to the image sensor described above with reference to FIGS. 4A, 4B, 4C, and 13B, and may include additional features not mentioned above. Consequently, repeated descriptions of the image sensor described above with reference to FIGS. 4A, 4B, 4C, and 13B may be omitted for the sake of brevity.

Referring to FIG. 19, an image sensor PA9 may be provided. In some example embodiments, a third stacked structure S3 may be provided. The third stacked structure S3 may include a third substrate region 300, a third upper wire insulating layer 320, third wires 322, a third lower wire insulating layer 324, a fourth connection pad CP4, and third transistors TR3. Each of the third substrate region 300, the third wires 322, and the third transistors TR3 may include and/or may be substantially similar in many respects to the second substrate region 200, the second wires 222, and the second transistors TR2. The third upper wire insulating layer 320 and the third lower wire insulating layer 324 may include and/or may be substantially similar in many respects to the second wire insulating layer 220. The fourth connection pad CP4 may extend from a bottom surface of the third substrate region 300 along the third direction DR3. The fourth connection pad CP4 may include, but not be limited to, electrically conductive materials (e.g., copper (Cu)).

The third wires 322 may be provided within the sensor array region SAR, the connection region C, and the pad region P. The third wires 322 may be provided in the third upper wire insulating layer 320. The third wires 322 may be electrically connected to the fourth connection pad CP4. The fourth connection pad CP4 may be provided within the pad region P. The third transistors TR3 may be provided within the connection region C and the pad region P. The illustrated positions of the third wires 322, the fourth connection pad CP4, and the third transistors TR3 are exemplary. That is, the present disclosure is not limited in this regard. The positions of the third wires 322, the fourth connection pad CP4, and the third transistors TR3 may be determined as needed, according to design constraints. The shapes and numbers of the illustrated third wires 322 and the fourth connection pad CP4 are exemplary. That is, the present disclosure is not limited in this regard. The shape and number of the third wires 322 and the fourth connection pad CP4 may be appropriately determined as needed, according to design constraints. The number of third transistors TR3 is exemplary. That is, the present disclosure is not limited in this regard. The number of third transistors TR3 may be appropriately determined as needed, according to design constraints.

The third stacked structure S3 may be provided between the first stacked structure S1 and the second stacked structure S2. The second stacked structure S2, the third stacked structure S3, and the first stacked structure S1 may be provided sequentially along the third direction DR3. In some example embodiments, the first conductive pad 144 and the second vias 146 may be provided to electrically connect the first and second stacked structures S1 and S2. For example, the fourth connection pad CP4 may be provided on the second connection pad CP2. The second and fourth connection pads CP2 and CP4 may be provided to electrically connect the second and third stacked structures S2 and S3.

The second vias 146 of FIG. 19 may include and/or may be substantially similar in many respects to the second vias 146 described above with reference to FIG. 13B.

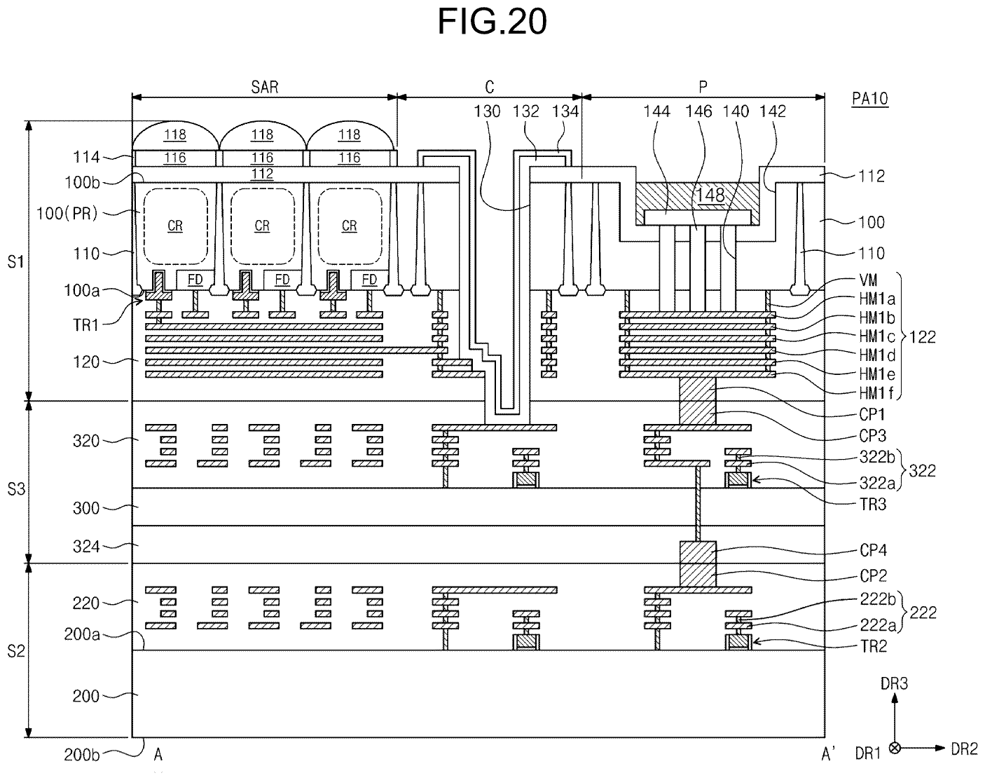

FIG. 20 is a cross-sectional view illustrating an image sensor, according to some example embodiments. The image sensor depicted in FIG. 20 may include and/or may be similar in many respects to the image sensor described above with reference to FIGS. 4A, 4B, and 4C, and may include additional features not mentioned above. Consequently, repeated descriptions of the image sensor described above with reference to FIGS. 4A, 4B, and 4C may be omitted for the sake of brevity.

Referring to FIG. 20, an image sensor PA10 may be provided. In some example embodiments, a third stacked structure S3 may be provided. The third stacked structure S3 may include a third substrate region 300, a third upper wire insulating layer 320, third wires 322, a third lower wire insulating layer 324, a third connection pad CP3, a fourth connection pad CP4, and third transistors TR3. Each of the third substrate region 300, the third wires 322, and the third transistors TR3 may include and/or may be substantially similar in many respects to the second substrate region 200, the second wires 222, and the second transistors TR2. The third upper wire insulating layer 320 and the third lower wire insulating layer 324 may include and/or may be substantially similar in many respects to the second wire insulating layer 220. The third connection pad CP3 may extend from a top surface of the third upper wire insulating layer 320 along a direction opposite to the third direction DR3. The fourth connection pad CP4 may extend from a bottom surface of the third substrate region 300 along the third direction DR3. The third and fourth connection pads CP3 and CP4 may include, but not be limited to, electrically conductive materials (e.g., copper (Cu)).

The third wires 322 may be provided within the sensor array region SAR, the connection region C, and the pad region P. The third wires 322 may be provided in the third upper wire insulating layer 320. The third wires 322 may be electrically connected to the fourth connection pad CP4. The third and fourth connection pads CP3 and CP4 may be provided within the pad region P. The third transistors TR3 may be provided within the connection region C and the pad region P. The illustrated positions of the third wires 322, the third connection pad CP3, the fourth connection pad CP4, and the third transistors TR3 are exemplary. That is, the present disclosure is not limited in this regard. The positions of the third wires 322, the third connection pad CP3, the fourth connection pad CP4, and the third transistors TR3 may be determined as needed, according to design constraints. The shapes and numbers of the illustrated third wires 322, third connection pad CP3, and fourth connection pad CP4 are illustrative. The shape and number of the third wires 322, the third connection pad CP3, and the fourth connection pad CP4 may be appropriately determined as needed, according to design constraints. The number of third transistors TR3 is exemplary. That is, the present disclosure is not limited in this regard. The number of third transistors TR3 may be appropriately determined as needed, according to design constraints.

The third stacked structure S3 may be provided between the first stacked structure S1 and the second stacked structure S2. The second stacked structure S2, the third stacked structure S3, and the first stacked structure S1 may be provided sequentially along the third direction DR3. In some example embodiments, the first connection pad CP1 may be provided on the third connection pad CP3. The first and third connection pads CP1 and CP3 may be provided to electrically connect the first and second stacked structures S1 and S2. For example, the fourth connection pad CP4 may be provided on the second connection pad CP2. The second and fourth connection pads CP2 and CP4 may be provided to electrically connect the second and third stacked structures S2 and S3.

The first wires 122 may be provided. The first wires 122 may include the first horizontal wire HM1a, the second horizontal wire HM1b, the third horizontal wire HM1c, the fourth horizontal wire HM1d, the fifth horizontal wire HM1e, the sixth horizontal wire HM1f, and the first vertical wires VM. For example, the first to sixth horizontal wires HM1a to HM1f may be provided along a direction parallel to the first surface 100a (e.g., the first direction DR1, the second direction DR2, or a combined direction of the first direction DR1 and the second direction DR2). For example, the second vias 146 may be provided to be electrically connected to the first horizontal wire HM1a.

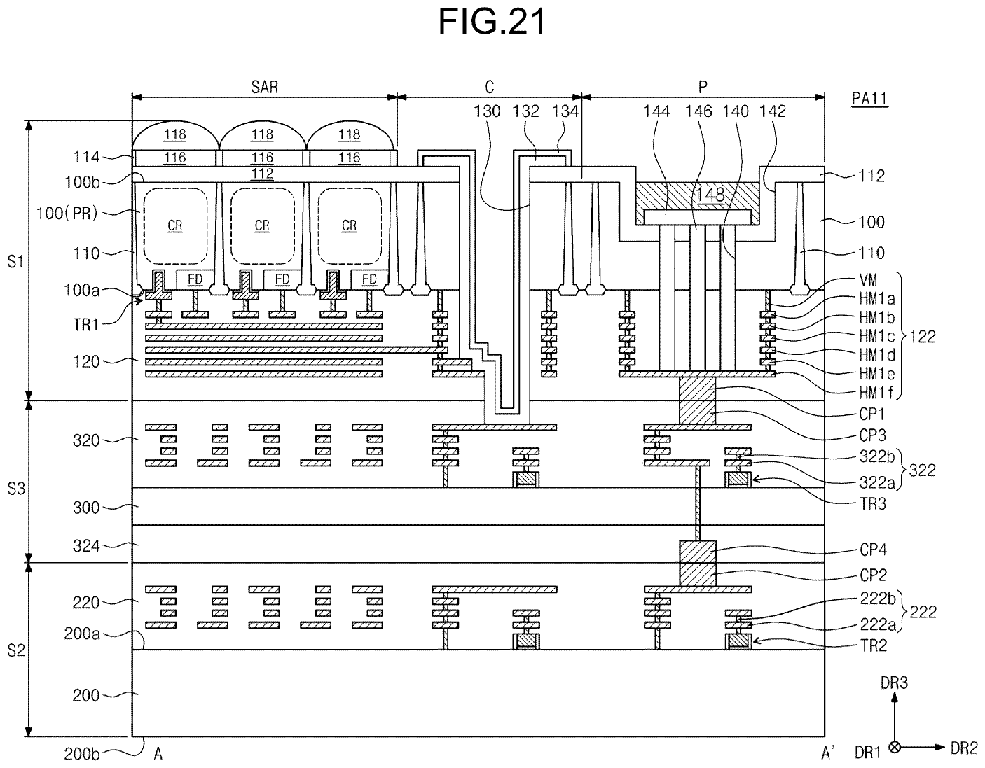

FIG. 21 is a cross-sectional view illustrating an image sensor, according to some example embodiments. The image sensor depicted in FIG. 21 may include and/or may be similar in many respects to the image sensor described above with reference to FIGS. 4A, 4B, and 4C, and may include additional features not mentioned above. Consequently, repeated descriptions of the image sensor described above with reference to FIGS. 4A, 4B, and 4C may be omitted for the sake of brevity.

Referring to FIG. 21, an image sensor PA11 may be provided. In some example embodiments, a third stacked structure S3 may be provided. The third stacked structure S3 may include a third substrate region 300, a third upper wire insulating layer 320, third wires 322, a third lower wire insulating layer 324, a third connection pad CP3, a fourth connection pad CP4, and third transistors TR3. Each of the third substrate region 300, the third wires 322, and the third transistors TR3 may include and/or may be substantially similar in many respects to the second substrate region 200, the second wire insulating layer 220, and the second wires 222, and the second transistors TR2. The third upper wire insulating layer 320 and the third lower wire insulating layer 324 may include and/or may be substantially similar in many respects to the second wire insulating layer 220. The third connection pad CP3 may extend from a top surface of the third upper wire insulating layer 320 along a direction opposite to the third direction DR3. The fourth connection pad CP4 may extend from a bottom surface of the third substrate region 300 along the third direction DR3. The third and fourth connection pads CP3 and CP4 may include, but not be limited to, electrically conductive materials (e.g., copper (Cu)).

The third wires 322 may be provided within the sensor array region SAR, the connection region C, and the pad region P. The third wires 322 may be provided in the third upper wire insulating layer 320. The third wires 322 may be electrically connected to the fourth connection pad CP4. The third and fourth connection pads CP3 and CP4 may be provided within the pad region P. The third transistors TR3 may be provided within the connection region C and the pad region P. The illustrated positions of the third wires 322, the third connection pad CP3, the fourth connection pad CP4, and the third transistors TR3 are exemplary. That is, the present disclosure is not limited in this regard. The positions of the third wires 322, the third connection pad CP3, the fourth connection pad CP4, and the third transistors TR3 may be determined as needed, according to design constraints. The shapes and numbers of the illustrated third wires 322, the third connection pad CP3, and the fourth connection pad CP4 are exemplary. That is, the present disclosure is not limited in this regard. The shape and number of the third wires 322, the third connection pad CP3, and the fourth connection pad CP4 may be appropriately determined as needed, according to design constraints. The number of third transistors TR3 illustrated is exemplary. That is, the present disclosure is not limited in this regard. The number of third transistors TR3 may be appropriately determined as needed, according to design constraints.

The third stacked structure S3 may be provided between the first stacked structure S1 and the second stacked structure S2. The second stacked structure S2, the third stacked structure S3, and the first stacked structure S1 may be provided sequentially along the third direction DR3. In some example embodiments, the first connection pad CP1 may be provided on the third connection pad CP3. The first and third connection pads CP1 and CP3 may be provided to electrically connect the first and second stacked structures S1 and S2. For example, the fourth connection pad CP4 may be provided on the second connection pad CP2. The second and fourth connection pads CP2 and CP4 may be provided to electrically connect the second and third stacked structures S2 and S3.

The first wires 122 may be provided. The first wires 122 may include the first horizontal wire HM1a, the second horizontal wire HM1b, the third horizontal wire HM1c, the fourth horizontal wire HM1d, the fifth horizontal wire HM1e, the sixth horizontal wire HM1f, and the first vertical wires VM. For example, the first to fifth horizontal wires HM1a to HM1e may be provided to surround the second vias 146 from a plan view. For example, the sixth horizontal wire HM1f may be provided along a direction parallel to the first surface 100a (e.g., the first direction DR1, the second direction DR2, or a combined direction of the first direction DR1 and the second direction DR2). In some example embodiments, the second vias 146 may be provided to be connected to the sixth horizontal wire HM1f. In some other example embodiments, the number of horizontal wires provided in the direction parallel to the first surface 100a may be determined as needed, according to design constraints. The number of horizontal wires provided to surround the second vias 146 may be determined as needed, according to design constraints. For example, the first and second horizontal wires HM1a and HM1b may surround the second vias 146, and the second vias 146 may be provided to be electrically connected to the third horizontal wire HM1c. For example, the first to third horizontal wires HM1a to HM1c may be provided to surround the second vias 146, and the second vias 146 may be electrically connected to the fourth horizontal wire HM1d. As another example, the first to fourth horizontal wires HM1a to HM1d may be provided to surround the second vias 146, and the second vias 146 may be electrically connected to the fifth horizontal wire HM1e.

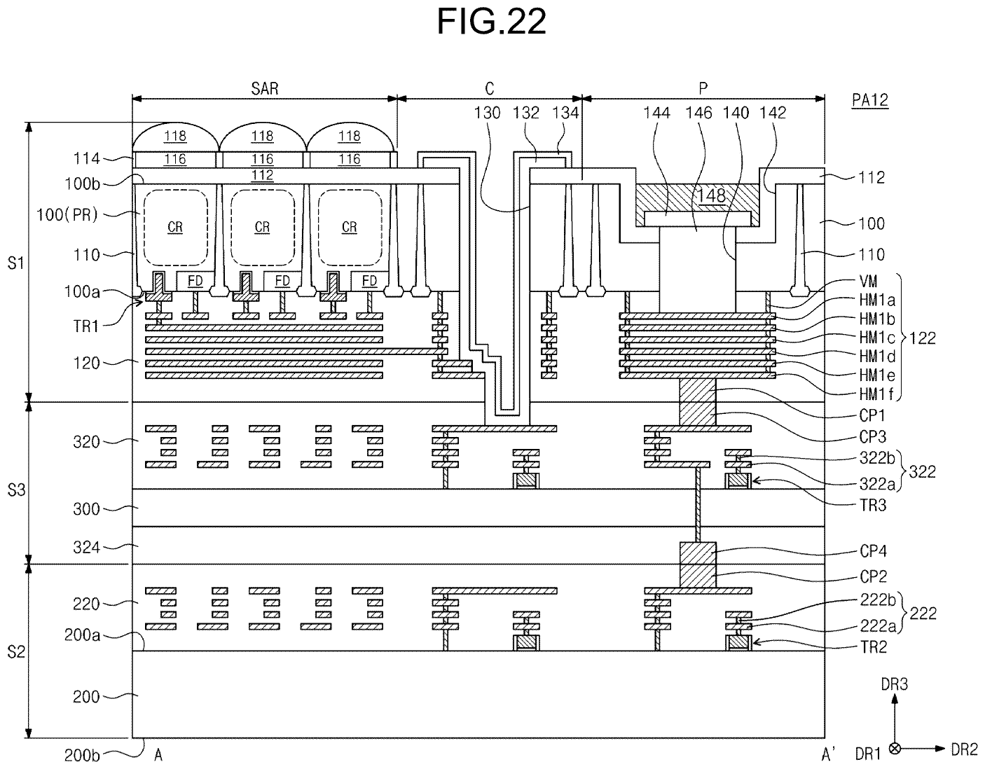

FIG. 22 is a cross-sectional view illustrating an image sensor, according to some example embodiments. The image sensor depicted in FIG. 22 may include and/or may be similar in many respects to the image sensor described above with reference to FIGS. 4A, 4B, 4C, and 13B, and may include additional features not mentioned above. Consequently, repeated descriptions of the image sensor described above with reference to FIGS. 4A, 4B, 4C, and 13B may be omitted for the sake of brevity.

Referring to FIG. 22, an image sensor PA12 may be provided. In some example embodiments, a third stacked structure S3 may be provided. The third stacked structure S3 may include a third substrate region 300, a third upper wire insulating layer 320, third wires 322, a third lower wire insulating layer 324, a third connection pad CP3, a fourth connection pad CP4, and third transistors TR3. Each of the third substrate region 300, the third wires 322, and the third transistors TR3 may include and/or may be substantially similar in many respects to the second substrate region 200, the second wires 222, and the second transistors TR2. The third upper wire insulating layer 320 and the third lower wire insulating layer 324 may include and/or may be substantially similar in many respects to the second wire insulating layer 220. The third connection pad CP3 may extend from a surface of the third upper wire insulating layer 320 along a direction opposite to the third direction DR3. The fourth connection pad CP4 may extend from a bottom surface of the third substrate region 300 along the third direction DR3. The third and fourth connection pads CP3 and CP4 may include, but not be limited to, electrically conductive materials (e.g., copper (Cu)).

The third wires 322 may be provided within the sensor array region SAR, the connection region C, and the pad region P. The third wires 322 may be provided in the third upper wire insulating layer 320. The third wires 322 may be electrically connected to the fourth connection pad CP4. The third and fourth connection pads CP3 and CP4 may be provided within the pad region P. The third transistors TR3 may be provided within the connection region C and the pad region P. The illustrated positions of the third wires 322, the third connection pad CP3, the fourth connection pad CP4, and the third transistors TR3 are exemplary. That is, the present disclosure is not limited in this regard. The positions of the third wires 322, the third connection pad CP3, the fourth connection pad CP4, and the third transistors TR3 may be determined as needed, according to design constraints. The shapes and numbers of the illustrated third wires 322, the third connection pad CP3, and the fourth connection pad CP4 are illustrative. The shape and number of the third wires 322, the third connection pad CP3, and the fourth connection pad CP4 may be appropriately determined as needed, according to design constraints. The number of third transistors TR3 illustrated is exemplary. That is, the present disclosure is not limited in this regard. The number of third transistors TR3 may be appropriately determined as needed, according to design constraints.

The third stacked structure S3 may be provided between the first stacked structure S1 and the second stacked structure S2. The second stacked structure S2, the third stacked structure S3, and the first stacked structure S1 may be provided sequentially along the third direction DR3. In some example embodiments, the first connection pad CP1 may be provided on the third connection pad CP3. The first and third connection pads CP1 and CP3 may be provided to electrically connect the first and second stacked structures S1 and S2. For example, the fourth connection pad CP4 may be provided on the second connection pad CP2. The second and fourth connection pads CP2 and CP4 may be provided to electrically connect the second and third stacked structures S2 and S3.

The first wires 122 may be provided. The first wires 122 may include the first horizontal wire HM1a, the second horizontal wire HM1b, the third horizontal wire HM1c, the fourth horizontal wire HM1d, the fifth horizontal wire HM1e, the sixth horizontal wire HM1f, and the first vertical wires VM. For example, the first to sixth horizontal wires HM1a to HM1f may be provided along a direction parallel to the first surface 100a (e.g., the first direction DR1, the second direction DR2, or a combined direction of the first direction DR1 and the second direction DR2). For example, the second vias 146 may be provided to be electrically connected to the first horizontal wire HM1a.

The second vias 146 of FIG. 22 may include and/or may be substantially similar in many respects to the second vias 146 described above with reference to FIG. 13B.

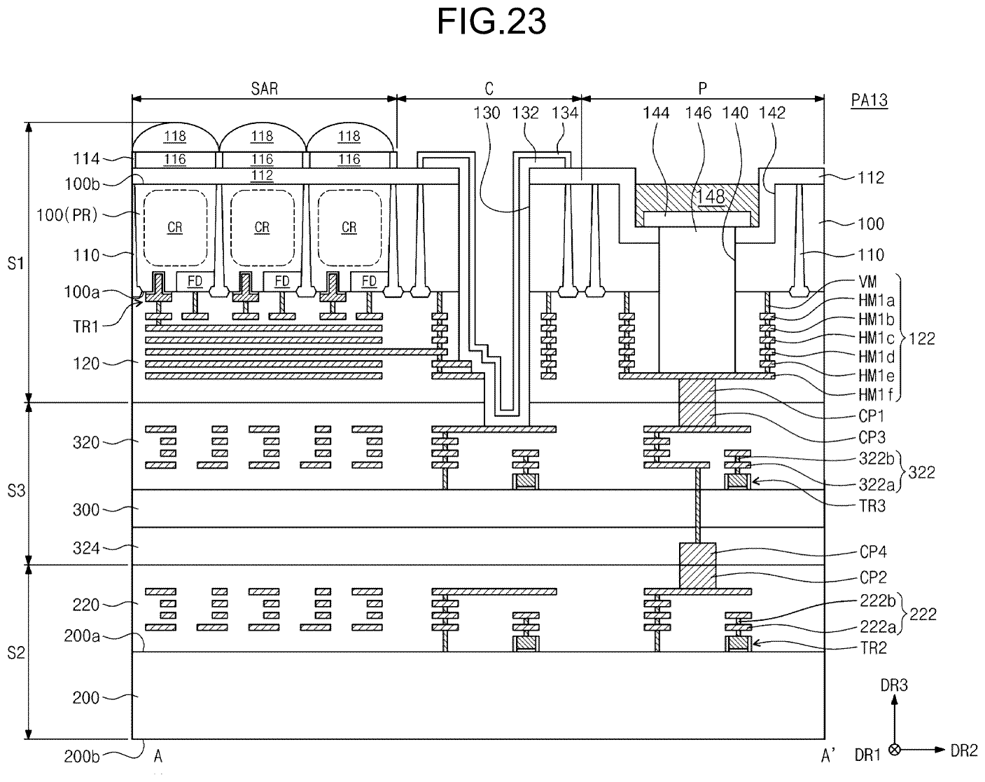

FIG. 23 is a cross-sectional view illustrating an image sensor, according to some example embodiments. The image sensor depicted in FIG. 23 may include and/or may be similar in many respects to the image sensor described above with reference to FIGS. 4A, 4B, 4C, and 13B, and may include additional features not mentioned above. Consequently, repeated descriptions of the image sensor described above with reference to FIGS. 4A, 4B, 4C, and 13B may be omitted for the sake of brevity.

Referring to FIG. 23, an image sensor PA13 may be provided. In some example embodiments, a third stacked structure S3 may be provided. The third stacked structure S3 may include a third substrate region 300, a third upper wire insulating layer 320, third wires 322, a third lower wire insulating layer 324, a third connection pad CP3, a fourth connection pad CP4, and a third transistors TR3. Each of the third substrate region 300, the third wires 322, and the third transistors TR3 may include and/or may be substantially similar in many respects to the second substrate region 200, the second wires 222, and the second transistors TR2. The third upper wire insulating layer 320 and the third lower wire insulating layer 324 may include and/or may be substantially similar in many respects to the second wire insulating layer 220. The third connection pad CP3 may extend from a top surface of the third upper wire insulating layer 320 along a direction opposite to the third direction DR3. The fourth connection pad CP4 may extend from a bottom surface of the third substrate region 300 along the third direction DR3. The third and fourth connection pads CP3 and CP4 may include, but not be limited to, electrically conductive materials (e.g., copper (Cu)).

The third wires 322 may be provided within the sensor array region SAR, the connection region C, and the pad region P. The third wires 322 may be provided in the third upper wire insulating layer 320. The third wires 322 may be electrically connected to the fourth connection pad CP4. The third and fourth connection pads CP3 and CP4 may be provided within the pad region P. The third transistors TR3 may be provided within the connection region C and the pad region P. The illustrated positions of the third wires 322, the third connection pad CP3, the fourth connection pad CP4, and the third transistors TR3 are exemplary. That is, the present disclosure is not limited in this regard. The positions of the third wires 322, the third connection pad CP3, the fourth connection pad CP4, and the third transistors TR3 may be determined as needed, according to design constraints. The shapes and numbers of the illustrated third wires 322, the third connection pad CP3, and the fourth connection pad CP4 are illustrative. The shape and number of the third wires 322, the third connection pad CP3, and the fourth connection pad CP4 may be appropriately determined as needed, according to design constraints. The number of third transistors TR3 illustrated is exemplary. That is, the present disclosure is not limited in this regard. The number of third transistors TR3 may be appropriately determined as needed, according to design constraints.

The third stacked structure S3 may be provided between the first stacked structure S1 and the second stacked structure S2. The second stacked structure S2, the third stacked structure S3, and the first stacked structure S1 may be provided sequentially along the third direction DR3. In some example embodiments, the first connection pad CP1 may be provided on the third connection pad CP3. The first and third connection pads CP1 and CP3 may be provided to electrically connect the first and second stacked structures S1 and S2. For example, the fourth connection pad CP4 may be provided on the second connection pad CP2. The second and fourth connection pads CP2 and CP4 may be provided to electrically connect the second and third stacked structures S2 and S3.

The first wires 122 may be provided. The first wires 122 may include the first horizontal wire HM1a, the second horizontal wire HM1b, the third horizontal wire HM1c, the fourth horizontal wire HM1d, the fifth horizontal wire HM1e, the sixth horizontal wire HM1f, and the first vertical wires VM. For example, the first to fifth horizontal wires HM1a to HM1e may be provided to surround the second vias 146 from a plan view. For example, the sixth horizontal wire HM1f may be provided along a direction parallel to the first surface 100a (e.g., the first direction DR1, the second direction DR2, or a combined direction of the first direction DR1 and the second direction DR2). In some example embodiments, the second vias 146 may be provided to be connected to the sixth horizontal wire HM1f. In some other example embodiments, the number of horizontal wires provided in the direction parallel to the first surface 100a may be determined as needed, according to design constraints. The number of horizontal wires provided to surround the second vias 146 may be determined as needed, according to design constraints. For example, the first and second horizontal wires HM1a and HM1b may surround the second vias 146, and the second vias 146 may be provided to be electrically connected to the third horizontal wire HM1c. For example, the first to third horizontal wires HM1a to HM1c may be provided to surround the second vias 146, and the second vias 146 may be electrically connected to the fourth horizontal wire HM1d. For example, the first to fourth horizontal wires HM1a to HM1d may be provided to surround the second vias 146, and the second vias 146 may be electrically connected to the fifth horizontal wire HM1e.

The second vias 146 of FIG. 23 may include and/or may be substantially similar in many respects to the second vias 146 described above with reference to FIG. 13B.

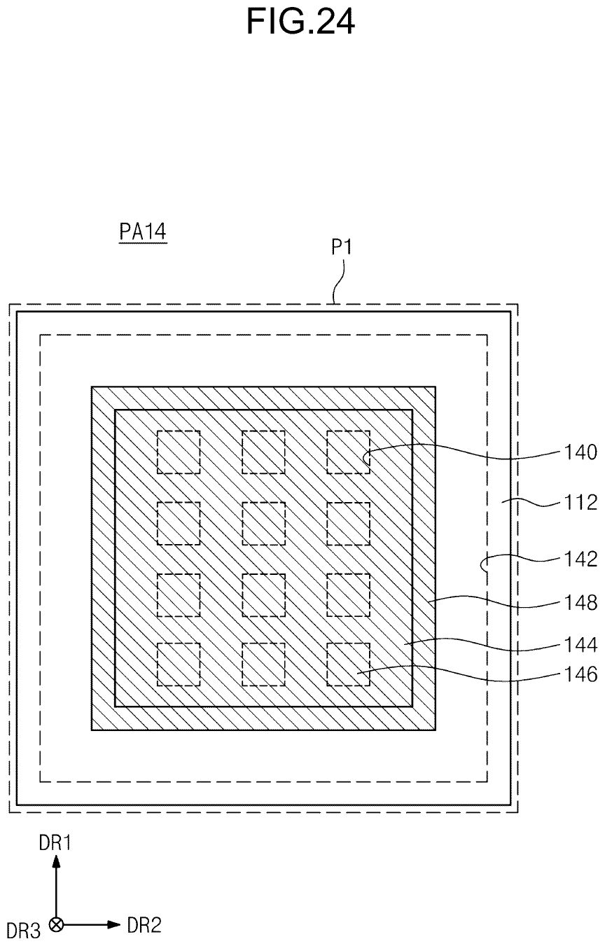

FIG. 24 is a cross-sectional view illustrating an image sensor, according to some example embodiments. The image sensor depicted in FIG. 24 may include and/or may be similar in many respects to the image sensor described above with reference to FIGS. 4A, 4B, and 4C, and may include additional features not mentioned above. Consequently, repeated descriptions of the image sensor described above with reference to FIGS. 4A, 4B, and 4C may be omitted for the sake of brevity.

Referring to FIG. 24, an image sensor PA14 may be provided. In some example embodiments, the second vias 146 may be arranged in rows extending along the second direction DR2 and columns extending along the first direction DR1. In some example embodiments, from a plan view, the second vias 146 may be arranged in four rows extending along the second direction DR2 and three columns extending along the first direction DR1. The number of rows and columns of the second vias 146 may be determined as needed, according to design constraints.

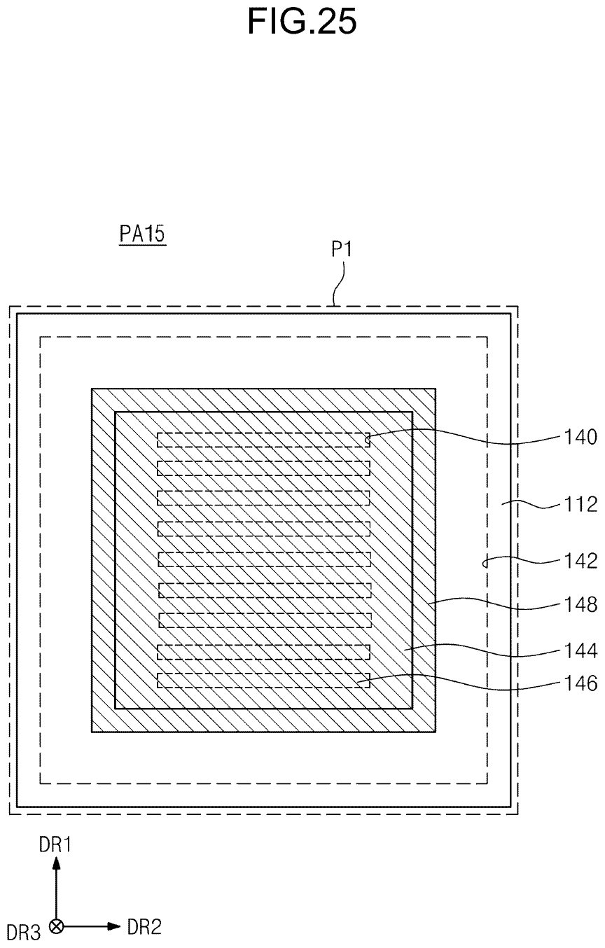

FIG. 25 is a cross-sectional view illustrating an image sensor, according to some example embodiments. The image sensor depicted in FIG. 25 may include and/or may be similar in many respects to the image sensor described above with reference to FIGS. 13A and 13B, and may include additional features not mentioned above. Consequently, repeated descriptions of the image sensor described above with reference to FIGS. 13A and 13B may be omitted for the sake of brevity.

Referring to FIG. 25, an image sensor PA15 may be provided. In some example embodiments, the second vias 146 may be arranged in rows extending along the first direction DR1. In some example embodiments, from a plan view, the second vias 146 may be arranged in nine rows extending along the first direction DR1. The number of rows of second vias 146 may be determined as needed, according to design constraints.

The above description of some example embodiments of the present disclosure provides examples describing the technical idea of the present disclosure. Therefore, the present disclosure is not limited to the above some example embodiments. Within the technical idea of the present disclosure, various modifications and changes are possible, such as combining the above some example embodiments by those skilled in the art.

What is claimed is:

1. An image sensor, comprising:
a first substrate region comprising a first surface and a second surface;
a pad groove adjacent to the second surface;
a first conductive pad in the pad groove;
a second conductive pad on the first conductive pad and within the pad groove; and
a plurality of vias electrically coupled with the first conductive pad and at least partially penetrating the first substrate region.

2. The image sensor according to claim 1, wherein a top surface of the second conductive pad is positioned at a first level that is lower than or equal to a second level of the second surface.

3. The image sensor according to claim 1, wherein the second conductive pad at least partially covers a side surface of the first conductive pad.

4. The image sensor according to claim 1, further comprising:
a lower insulating layer extending along a surface of the first substrate region exposed by the pad groove,
wherein the first conductive pad and the second conductive pad are spaced apart from the first substrate region by the lower insulating layer, and
wherein the plurality of vias at least partially penetrate the lower insulating layer.

5. The image sensor according to claim 1, further comprising:
a plurality of first horizontal wires on the first surface,
wherein the plurality of vias are in contact with the plurality of first horizontal wires.

6. The image sensor according to claim 5, wherein the plurality of vias are in contact with at least one of the plurality of first horizontal wires that is closest to the second surface.

7. The image sensor according to claim 5, further comprising:
a second substrate region on the first surface;
a plurality of second horizontal wires between the second substrate region and the plurality of first horizontal wires;
a first connection pad between the plurality of first horizontal wires and the plurality of second horizontal wires; and
a second connection pad between the first connection pad and the plurality of second horizontal wires.

8. The image sensor according to claim 1, further comprising:
a second substrate region on the first surface;
a first wire insulating layer between the first substrate region and the second substrate region;
a plurality of first horizontal wires in the first wire insulating layer;
a second wire insulating layer between the first wire insulating layer and the second substrate region, and
a plurality of second horizontal wires in the second wire insulating layer,
wherein the plurality of vias are electrically coupled with the plurality of second horizontal wires.

9. The image sensor according to claim 8, wherein the plurality of vias are in contact with at least one of the plurality of second horizontal wires that is closest to the first wire insulating layer.

10. The image sensor according to claim 1, wherein the plurality of vias are disposed along a first direction and a second direction,
wherein the first direction and the second direction are parallel to the first surface, and
wherein the first direction and the second direction intersect each other.

11. The image sensor according to claim 1, wherein the plurality of vias are disposed in a first direction parallel to the first surface; and
wherein each of the plurality of vias has a line shape extending along a second direction intersecting with the first direction.

12. A method of manufacturing an image sensor, the method comprising:
forming a second substrate region on a first surface of a first substrate region comprising the first surface and a second surface;
forming a pad groove by etching the first substrate region adjacent to the second surface;
forming a first conductive pad in the pad groove;
forming a second conductive pad at least partially covering the first conductive pad in the pad groove;
exposing the first conductive pad and forming holes at least partially penetrating the first substrate region; and
forming a plurality of vias electrically coupled with the first conductive pad in the holes,
wherein the second conductive pad is within the pad groove.

13. The method of manufacturing the image sensor according to claim 12, further comprising:
forming a lower insulating layer extending along a surface of the first substrate region exposed by the pad groove,
wherein the first conductive pad and the second conductive pad are spaced apart from the first substrate region by the lower insulating layer, and
wherein the plurality of vias at least partially penetrate the lower insulating layer.

14. The method of manufacturing the image sensor according to claim 13, wherein the forming of the first conductive pad comprises:
forming a conductive layer on the lower insulating layer; and
patterning the conductive layer such that a side surface of the first conductive pad is spaced apart from the lower insulating layer.

15. The method of manufacturing the image sensor according to claim 12, further comprising:
forming a plurality of first horizontal wires between the first substrate region and the second substrate region;
forming a plurality of second horizontal wires between the plurality of first horizontal wires and the second substrate region;
forming a first connection pad between the plurality of first horizontal wires and the plurality of second horizontal wires; and
forming a second connection pad between the first connection pad and the plurality of second horizontal wires,
wherein the plurality of vias are in contact with the plurality of first horizontal wires.

16. The method of manufacturing the image sensor according to claim 12, further comprising:
forming a first wire insulating layer between the first substrate region and the second substrate region;
forming a plurality of first horizontal wires in the first wire insulating layer;
forming a second wire insulating layer between the first wire insulating layer and the second substrate region; and
forming a plurality of second horizontal wires in the second wire insulating layer,
wherein the holes expose the plurality of second horizontal wires by at least partially penetrating the first wire insulating layer and the second wire insulating layer between the plurality of second horizontal wires and the first substrate region, and
wherein the plurality of vias are in contact with the plurality of second horizontal wires.

17. The method of manufacturing the image sensor according to claim 12, wherein the holes are disposed in a first direction parallel to the first surface, and
wherein each of the holes has a line shape extending along a second direction intersecting with the first direction.

18. An image sensor, comprising:
a first stacked structure;
a second stacked structure electrically coupled with the first stacked structure;
a pad groove on an opposite side of the second stacked structure with respect to the first stacked structure;
a first conductive pad in the pad groove;
a second conductive pad on the first conductive pad and positioned in the pad groove; and
a plurality of vias extending from the first conductive pad toward the second stacked structure,
wherein a top surface of the second conductive pad is positioned at a first level lower than or equal to a second level of a second surface of the first conductive pad.

19. The image sensor according to claim 18, wherein the first stacked structure comprises:
a first substrate region;
a first wire insulating layer between the first substrate region and the second stacked structure; and
a plurality of first horizontal wires in the first wire insulating layer, and
wherein the second stacked structure comprises:
a second substrate region;
a second wire insulating layer between the second substrate region and the first stacked structure; and
a plurality of second horizontal wires in the second wire insulating layer, and
wherein the plurality of vias are in contact with the plurality of second horizontal wires.

20. The image sensor according to claim 18, wherein the first stacked structure comprises:
a first substrate region;
a first wire insulating layer between the first substrate region and the second stacked structure;
a plurality of first horizontal wires in the first wire insulating layer; and
a first connection pad between the plurality of first horizontal wires and the second stacked structure,
wherein the second stacked structure comprises:
a second substrate region;
a second wire insulating layer between the second substrate region and the first stacked structure;
a plurality of second horizontal wires in the second wire insulating layer; and
a second connection pad between the plurality of second horizontal wires and the first stacked structure,
wherein the plurality of vias are in contact with the plurality of first horizontal wires, and
wherein the first connection pad and the second connection pad are in contact with each other.
